(19) United States
(12) Patent Application Publication
(10) Pub. No.: US 2025/0260373 A1
(43) Pub. Date: Aug. 14, 2025

(54) AMPLIFIER CIRCUIT

(71) Applicant: Murata Manufacturing Co., Ltd., Nagaokakyo-shi (JP)

(72) Inventor: Keisuke ARIMA, Nagaokakyo-shi (JP)

(73) Assignee: Murata Manufacturing Co., Ltd., Nagaokakyo-shi (JP)

(21) Appl. No.: 18/916,781

(22) Filed: Oct. 16, 2024

(30) Foreign Application Priority Data
Feb. 14, 2024 (JP) 2024-020630

(51) Int. Cl. H03F 3/217; H03F 3/21; H03F 3/213

(52) U.S. Cl. CPC H03F 3/2178; H03F 3/211; H03F 3/213; H03F 3/2176

(57) ABSTRACT

An amplifier circuit 1 includes a power amplifier circuit that includes a power amplifier, a power amplifier circuit that includes a power amplifier in which the phase of a fundamental wave at an output end is delayed by 90 degrees with respect to the power amplifier, and an in-phase combiner circuit that is configured to combine a fundamental wave of a first output signal output from the power amplifier circuit and a fundamental wave of a second output signal output from the power amplifier circuit. The power amplifier circuit is of an inverse class-E type. The power amplifier circuit is of a class-E type.

### CROSS-REFERENCE TO RELATED APPLICATION

This application claims priority to Japanese Patent Application No. JP 2024-020630 filed on Feb. 14, 2024. The entire contents of the above-identified application, including the specification, drawings and claims, are incorporated herein by reference in their entirety.

### BACKGROUND OF THE DISCLOSURE

### 1. Field of the Disclosure

The present disclosure relates to an amplifier circuit.

### 2. Description of the Related Art

In Japanese Unexamined Patent Application Publication No. 63-153904, a power amplifier that includes a first amplifier device and a second amplifier device that form a balanced amplifier and perform a class-F operation, and a filter that is connected between an output end of the first amplifier device and an output end of the second amplifier device and allows second-order harmonic waves to pass therethrough, is disclosed. By canceling second-order harmonic waves at the output end of the first amplifier device and the output end of the second amplifier device, power efficiency of fundamental waves can be improved.

### SUMMARY OF THE DISCLOSURE

However, in the power amplifier disclosed in Japanese Unexamined Patent Application Publication No. 63-153904, due to the class-F operation of the amplifier device, the frequency range of even-order harmonic waves in which load impedance is short-circuited is narrow, and it is thus difficult to accurately cancel second-order harmonic waves over the entire range of a band, for example, defined by 3rd Generation Partnership Project (3GPP (registered trademark)) so that high power efficiency can be ensured.

The present disclosure has been designed to solve the above-mentioned problem and an object of the present disclosure is to provide an amplifier circuit capable of suppressing harmonic waves accurately.

In order to achieve the object described above, an amplifier circuit according to an aspect of the present disclosure includes a first power amplifier circuit that includes a first power amplifier; a second power amplifier circuit that includes a second power amplifier in which a phase of a fundamental wave at an output end is delayed by 90 degrees with respect to the first power amplifier; and a combiner circuit that is configured to combine a fundamental wave of a first output signal output from the first power amplifier circuit and a fundamental wave of a second output signal output from the second power amplifier circuit. The first power amplifier circuit is of an inverse class-E type. The second power amplifier circuit is of a class-E type.

An amplifier circuit according to an aspect of the present disclosure includes a splitter that has a first input end, a first output end, and a second output end and is configured to split a fundamental wave signal in a transmission band of a first band input to the first input end, output from the first output end a first signal, and output from the second output end a second signal whose phase is −90 degrees with respect to a phase of the first signal; a first power amplifier that has a fourth input end and a fourth output end, the fourth input end being connected to the first output end; a second power amplifier that has a fifth input end and a fifth output end, the fifth input end being connected to the second output end; a combiner that has a second input end, a third input end, and a third output end and is configured to output from the third output end a third output signal obtained by combining in an in-phase manner a first output signal output from the first power amplifier and input through the second input end and a second output signal output from the second power amplifier and input through the third input end; a first phase shift circuit that is connected between the first power amplifier and the combiner and is configured to shift phases of a fundamental wave and a harmonic wave in the first band; a second phase shift circuit that is connected between the second power amplifier and the combiner and is configured to shift the phases of the fundamental wave and the harmonic wave in the first band in such a manner that a pass phase of the fundamental wave is +90 degrees with respect to the first phase shift circuit; a first harmonic wave phase shift circuit that is connected to a path connecting the fourth output end to the second input end and is configured to shift the phase of the harmonic wave; and a second harmonic wave phase shift circuit that is connected to a path connecting the fifth output end to the third input end and is configured to shift the phase of the harmonic wave. A phase shift difference obtained by subtracting the phase of the harmonic wave at the third input end from the phase of the harmonic wave at the second input end is larger than 90 degrees.

According to the present disclosure, an amplifier circuit capable of accurately suppressing harmonic waves can be provided.

### BRIEF DESCRIPTION OF THE DRAWINGS

FIG. 1 is a circuit configuration diagram of an amplifier circuit according to an embodiment;

FIG. 2 includes Smith charts illustrating harmonic wave impedances of a first power amplifier circuit and a second power amplifier circuit in the embodiment;

FIG. 3 is a circuit configuration diagram of an amplifier circuit according to a comparative example;

FIG. 4A is a diagram illustrating an example of the circuit configuration of a first harmonic wave phase shift circuit in the embodiment;

FIG. 4B is a diagram illustrating an example of the circuit configuration of a second harmonic wave phase shift circuit in the embodiment;

FIG. 4C is a diagram illustrating an example of the circuit configuration of a first phase shift circuit in the embodiment;

FIG. 4D is a diagram illustrating an example of the circuit configuration of a second phase shift circuit in the embodiment;

FIG. 5 is a circuit configuration diagram of an amplifier circuit according to a first modification of the embodiment;

FIG. 6 is a circuit configuration diagram of an amplifier circuit according to a second modification of the embodiment;

FIG. 7 is a circuit configuration diagram of an amplifier circuit according to a third modification of the embodiment;

FIG. 8A is a circuit configuration diagram of an amplifier circuit according to a fourth modification of the embodiment;

FIG. 8B is a circuit configuration diagram of an amplifier circuit according to a fifth modification of the embodiment; and

FIG. 9 is a circuit configuration diagram of an amplifier circuit according to a sixth modification of the embodiment.

### DESCRIPTION OF THE PREFERRED EMBODIMENTS

Hereinafter, embodiments of the present disclosure will be described in detail with reference to drawings. The embodiments described below each illustrate a comprehensive or specific example. Numerical values, shapes, materials, component elements, arrangements of the component elements, manners in which the component elements are connected, and so on illustrated in the embodiments described below are merely examples and are not intended to limit the present disclosure.

The drawings are schematic diagrams in which emphasis, omission, or ratio adjustment is performed in an appropriate manner in order that the present disclosure is illustrated. The drawings are not necessarily strictly illustrated and may differ from actual shapes, positional relationships, and ratios. In the drawings, substantially the same configurations are denoted by the same reference signs, and repetitive description may be omitted or simplified.

Furthermore, in the present disclosure, terms, such as parallel and perpendicular, representing the relationship between elements, terms, such as rectangular, representing the shape of an element, and numerical ranges do not represent only strict meanings but mean inclusion of substantially equivalent ranges, for example, differences on the order of a few percent.

In a circuit configuration of the present disclosure, “being connected” not only represents being directly connected by a connection terminal and/or a wire conductor but also includes being electrically connected with another circuit element interposed therebetween. “Being connected between A and B” may be understood as being connected to both A and B between A and B.

Furthermore, in the present disclosure, a “path” represents a transfer line including a wire through which a high frequency signal propagates, an electrode directly connected to the wire, a terminal directly connected to the wire or the electrode, and the like.

Furthermore, in the present disclosure, “a component A is arranged in series to a path B” may be understood as the state in which both a signal input end and a signal output end of the component A is connected to a wire, an electrode, or a terminal forming the path B.

In the present disclosure, a “terminal”, an “input end”, and an “output end” each represent a point at which a conductor inside an element terminates. In the case where the impedance of a conductor between elements is sufficiently low, a terminal is not only construed as a single point but also as an arbitrary point in the conductor between the elements or the entire conductor.

Furthermore, terms, such as “parallel” and “perpendicular”, representing the relationship between elements, terms, such as “rectangular”, representing the shape of an element, and numerical ranges do not represent only strict meanings but mean inclusion of substantially equivalent ranges, for example, differences on the order of a few percent.

A “pass band of a filter” is a part of a frequency spectrum that is transmitted through the filter and is defined as a frequency range in which output power is not attenuated from the maximum output power by 3 dB or more. Thus, a higher frequency end and a lower frequency end of a pass band of a band pass filter are identified as a higher frequency and a lower frequency at two points where output power is attenuated from the maximum output power by 3 dB.

A “transmission band” represents a frequency band used for transmission in a communication apparatus. A “reception band” represents a frequency band used for reception in the communication apparatus. For example, different frequency bands are used as a transmission band and a reception band in the case of frequency division duplex (FDD), and the same frequency band is used as a transmission band a reception band in the case of time division duplex (TDD). In particular, in the case of FDD, in the case where a communication apparatus is implemented in a user terminal (UE: user equipment) of a cellular network, an uplink band (uplink operation band) is used as a transmission band and a downlink band (downlink operation band) is used as a reception band. In contrast, in the case where a communication apparatus is implemented as a base station (BS) of a cellular network, a downlink band is used as a transmission band and an uplink band is used as a reception band.

A “pass phase” between two terminals of a high frequency signal is obtained by making a measurement RF probe in contact with the two terminals to measure bandpass characteristics (S21) by a network analyzer. Furthermore, a “reflection phase” at a terminal of a high frequency signal is obtained by making a measurement RF probe in contact with the terminal to measure bandpass characteristics (S11) by a network analyzer.

In the present disclosure, numerical values of a pass phase, a reflection phase, and a reflection phase difference do not represent only strict meanings but mean inclusion of substantially equivalent ranges, for example, differences of about 30 percent.

### Embodiment

### 1 Circuit Configuration of Amplifier Circuit 1

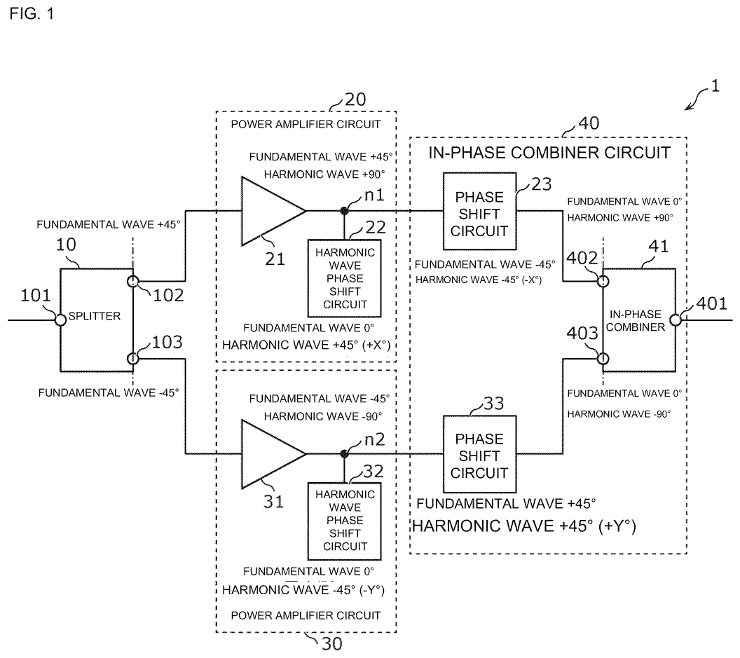

A circuit configuration of an amplifier circuit 1 will be described. FIG. 1 is a circuit configuration diagram of the amplifier circuit 1 according to an embodiment. As illustrated in the drawing, the amplifier circuit 1 includes a splitter 10, power amplifier circuits 20 and 30, and an in-phase combiner circuit 40.

The splitter 10 includes an input terminal 101 (first input end), an output terminal 102 (first output end), and an output terminal 103 (second output end). The splitter 10 is configured to split a fundamental wave signal in a transmission band of a first band input to the input terminal 101, output from the output terminal 102 a first signal, and output from the output terminal 103 a second signal whose phase is −90 degrees (delayed by 90 degrees) relative to a phase of the first signal. In this embodiment, the phase of the first signal is +45 degrees relative to the phase of the fundamental wave signal, and the phase of the second signal is −45 degrees relative to the phase of the fundamental wave signal. The amplifier circuit 1 does not necessarily include the splitter 10.

Furthermore, each of the input terminal and the output terminals in this embodiment may be a metal conductor such as a metal electrode or a metal bump or may be a point (node) on a metal wire.

The power amplifier circuit 20 is an example of a first power amplifier circuit and includes a power amplifier 21. The power amplifier 21 includes an amplifier transistor. The power amplifier 21 has a fourth input end and a fourth output end. The fourth input end is connected to the output terminal 102.

The power amplifier circuit 30 is an example of a second power amplifier circuit and includes a power amplifier 31. The power amplifier 31 includes an amplifier transistor. The power amplifier 31 includes a fifth input end and a fifth output end. The fifth input end is connected to the output terminal 103.

Since the power amplifier 21 amplifies the first signal output from the splitter 10 and the power amplifier 31 amplifies the second signal output from the splitter 10, the phase of a fundamental wave at the fifth output end of the power amplifier 31 is delayed by 90 degrees with respect to the phase of a fundamental wave at the fourth output end of the power amplifier 21. In this embodiment, the phase of the fundamental wave at the fourth output end of the power amplifier 21 is +45 degrees relative to the phase of the fundamental wave signal input to the input terminal 101 of the splitter 10, and the phase of the fundamental wave at the fifth output end of the power amplifier 31 is −45 degrees relative to the phase of the fundamental wave signal.

Furthermore, since the phase of the fundamental wave at the fifth output end of the power amplifier 31 is delayed by 90 degrees with respect to the phase of the fundamental wave at the fourth output end of the power amplifier 21, the phase of a second-order harmonic wave at the fifth output end of the power amplifier 31 is delayed by 180 degrees with respect to the phase of a second-order harmonic wave at the fourth output end of the power amplifier 21. In this embodiment, the phase of the second-order harmonic wave at the fourth output end of the power amplifier 21 is +90 degrees, and the phase of the second-order harmonic wave at the fifth output end of the power amplifier 31 is −90 degrees.

The power amplifier circuit 20 includes a harmonic wave phase shift circuit 22, in addition to the power amplifier 21. The harmonic wave phase shift circuit 22 is an example of a first harmonic wave phase shift circuit. The harmonic wave phase shift circuit 22 is connected to a path connecting the fourth output end of the power amplifier 21 to an in-phase combiner 41 and shifts the phase of a harmonic wave in the first band. The harmonic wave phase shift circuit 22 does not considerably shift the phase of a fundamental wave in the first band. In this embodiment, the pass phase of a second-order harmonic wave of the harmonic wave phase shift circuit 22 is +45 degrees.

The power amplifier circuit 30 includes a harmonic wave phase shift circuit 32, in addition to the power amplifier 31. The harmonic wave phase shift circuit 32 is an example of a second harmonic wave phase shift circuit. The harmonic wave phase shift circuit 32 is connected to a path connecting the fifth output end of the power amplifier 31 to the in-phase combiner 41 and shifts the phase of a harmonic wave in the first band. The harmonic wave phase shift circuit 32 does not considerably shift the phase of a fundamental wave in the first band. In this embodiment, the pass phase of a second-order harmonic wave of the harmonic wave phase shift circuit 32 is −45 degrees.

The amplifier transistor included in each of the power amplifiers 21 and 31 is, for example, a bipolar transistor such as a heterojunction bipolar transistor (HBT) or a field effect transistor such as a metal-oxide-semiconductor field effect transistor (MOSFET). In the case where the amplifier transistors mentioned above are bipolar transistors, the fourth input end of the power amplifier 21 and the fifth input end of the power amplifier 31 serve as, for example, base ends of the bipolar transistors and the fourth output end of the power amplifier 21 and the fifth output end of the power amplifier 31 serve as, for example, collector ends of the bipolar transistors. In the case where the amplifier transistors mentioned above are field effect transistors, the fourth input end of the power amplifier 21 and the fifth input end of the power amplifier 31 serve as, for example, gate ends of the field effect transistors and the fourth output end of the power amplifier 21 and the fifth output end of the power amplifier 31 serve as, for example, drain ends of the field effect transistors.

The in-phase combiner circuit 40 is an example of a combiner circuit and is configured to combine in an in-phase manner a first output signal output from the power amplifier circuit 20 and a second output signal output from the power amplifier circuit 30. The in-phase combiner circuit 40 includes the in-phase combiner 41 and phase shift circuits 23 and 33.

The in-phase combiner 41 is an example of a combiner and includes an input terminal 402 (second input end), an input terminal 403 (third input end), and an output terminal 401 (third output end). The in-phase combiner 41 is configured to output from the output terminal 401 a third output signal generated by combining in an in-phase manner the first output signal from the power amplifier circuit 20 input through the input terminal 402 and the second output signal from the power amplifier circuit 30 input through the input terminal 403.

The phase shift circuit 23 is an example of a first phase shift circuit and is connected between the power amplifier circuit 20 and the in-phase combiner 41. The phase shift circuit 23 is configured to shift phases of a fundamental wave and a harmonic wave in the first band. In this embodiment, the pass phase of the fundamental wave of the phase shift circuit 23 is −45 degrees, and the pass phase of the second-order harmonic wave is −45 degrees.

The phase shift circuit 33 is an example of a second phase shift circuit. The phase shift circuit 33 is connected between the power amplifier circuit 30 and the in-phase combiner 41 and is configured to shift the phases of the fundamental wave and the harmonic wave in the first band in such a manner that the pass phase of the fundamental wave in the first band is +90 degrees relative to that of the phase shift circuit 23. In this embodiment, the pass phase of the fundamental wave of the phase shift circuit 33 is +45 degrees, and the pass phase of the second-order harmonic wave is +45 degrees.

The pass phase of the second-order harmonic wave of the harmonic wave phase shift circuit 22 may be +X degrees (X>0), and the pass phase of the second-order harmonic wave of the phase shift circuit 23 may be −X degrees (X>0). That is, it is simply required that the pass phase of the second-order harmonic wave of a circuit consisting of the harmonic wave phase shift circuit 22 and the phase shift circuit 23 is 0 degrees.

Furthermore, the pass phase of the second-order harmonic wave of the harmonic wave phase shift circuit 32 may be −Y degrees (Y>0), and the pass phase of the second-order harmonic wave of the phase shift circuit 33 may be +Y degrees (Y>0). That is, it is simply required that the pass phase of the second-order harmonic wave of a circuit consisting of the harmonic wave phase shift circuit 32 and the phase shift circuit 33 is 0 degrees.

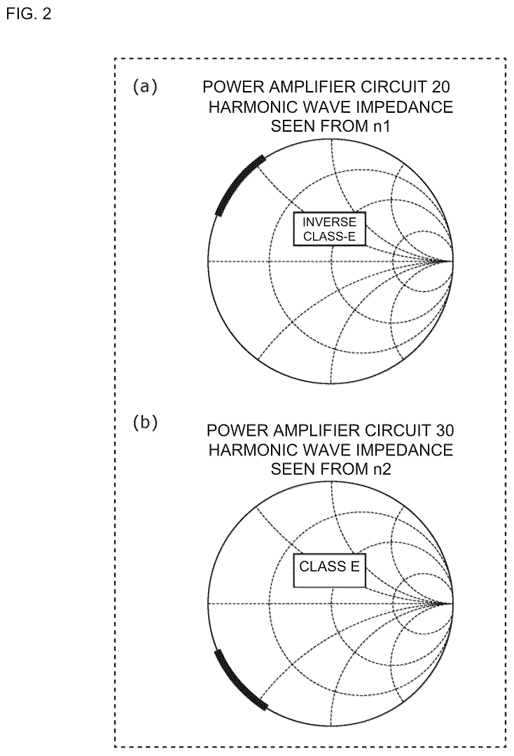

FIG. 2 includes Smith charts illustrating harmonic wave impedances of the power amplifier circuits 20 and 30 in this embodiment. As illustrated in the drawing, in the amplifier circuit 1 according to this embodiment, since the pass phase of the second-order harmonic wave of the harmonic wave phase shift circuit 22 is +45 degrees (+X degrees), the impedance of the second-order harmonic wave assuming the in-phase combiner circuit 40 side is seen from a connection point (node n1) between the fourth output end of the power amplifier 21 and the harmonic wave phase shift circuit 22 is located in the region of an inductive reactance (inductive impedance). In contrast, since the pass phase of the second-order harmonic wave of the harmonic wave phase shift circuit 32 is −45 degrees (−Y degrees), the impedance of the second-order harmonic wave assuming the in-phase combiner circuit 40 side is seen from a connection point (node n2) between the fifth output end of the power amplifier 31 and the harmonic wave phase shift circuit 32 is located in the region of a capacitive reactance (capacitive impedance).

That is, in the amplifier circuit 1 according to this embodiment, the power amplifier circuit 20 serves as an inverse class-E amplifier that makes the load impedance inductive with respect to the second-order harmonic wave, and the power amplifier circuit 30 serves as a class-E amplifier that makes the load impedance capacitive with respect to the second-order harmonic wave.

In other words, there is a phase difference of 90 degrees (or X+Y degrees) between the phase of the impedance with respect to the second-order harmonic wave at the node n1 of the power amplifier circuit 20 and the phase of the impedance with respect to the second-order harmonic wave at the node n2 of the power amplifier circuit 30.

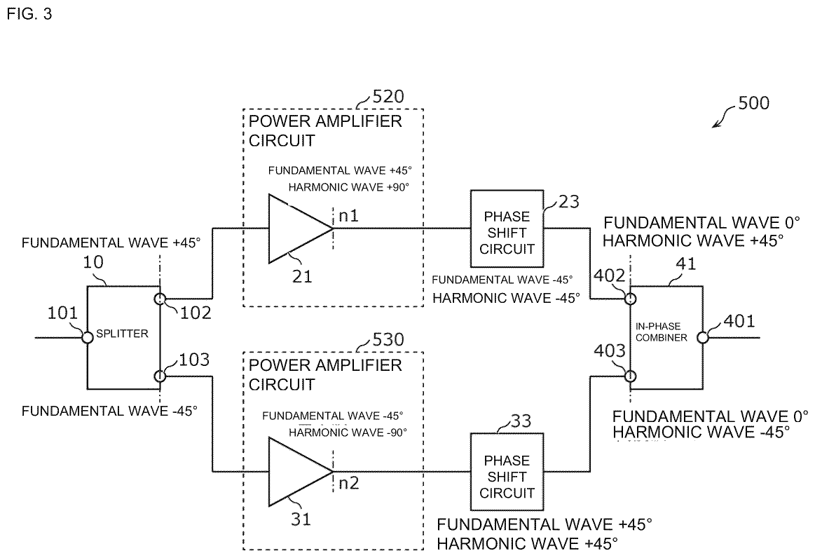

FIG. 3 is a circuit configuration diagram of an amplifier circuit 500 according to a comparative example. As illustrated in the drawing, the amplifier circuit 500 includes a splitter 10, power amplifier circuits 520 and 530, phase shift circuits 23 and 33, and an in-phase combiner 41. The amplifier circuit 500 according to the comparative example is different from the amplifier circuit 1 according to this embodiment in the configurations of the power amplifier circuits 520 and 530. Description of configuration features of the amplifier circuit 500 according to the comparative example that are the same as those of the amplifier circuit 1 according to the embodiment will be omitted, and different configuration features will be mainly described below.

The power amplifier circuit 520 includes a power amplifier 21. In this comparative example, the phase of a fundamental wave at the fourth output end (node n1) of the power amplifier 21 is +45 degrees relative to the phase of a fundamental wave signal input to the input terminal 101 of the splitter 10, and the phase of a second-order harmonic wave is +90 degrees.

The power amplifier circuit 530 includes a power amplifier 31. In this comparative example, the phase of a fundamental wave at the fifth output end (node n2) of the power amplifier 31 is −45 degrees relative to the phase of the fundamental wave signal input to the input terminal 101 of the splitter 10, and the phase of the second-order harmonic wave is −90 degrees.

With the configuration of the amplifier circuit 500 according to the comparative example described above, the phase of a fundamental wave of a first output signal at the node n1 output from the power amplifier 21 is +45 degrees, and the phase of the fundamental wave at the input terminal 402, after passing through the phase shift circuit 23, becomes 0 degrees. The phase of a fundamental wave of a second output signal at the node n2 output from the power amplifier 31 is −45 degrees, and the phase of the fundamental wave at the input terminal 403, after passing through the phase shift circuit 33, becomes 0 degrees. Thus, the fundamental wave signals in the first band are combined in an in-phase manner at the in-phase combiner 41 and output as a third output signal from the output terminal 401. Accordingly, the amplifier circuit 500 operates as a balanced amplifier that is resistant to changes in the load.

Meanwhile, the phase of a second-order harmonic wave of the first output signal at the node n1 output from the power amplifier 21 is +90 degrees, and the phase of the second-order harmonic wave at the input terminal 402, after passing through the phase shift circuit 23, becomes +45 degrees. Furthermore, the phase of a second-order harmonic wave of the second output signal at the node n2 output from the power amplifier 31 is −90 degrees, and the phase of the second-order harmonic wave at the input terminal 403, after passing through the phase shift circuit 33, becomes −45 degrees. Thus, the second-order harmonic waves in the first band have a phase difference of 90 degrees between the input terminals 402 and 403 of the in-phase combiner 41 and are not suppressed. Accordingly, neither the quality of transmission signals nor power efficiency is improved in the amplifier circuit 500.

In contrast, with the configuration of the amplifier circuit 1 according to this embodiment described above, the phase of the fundamental wave of the first output signal at the node n1 output from the power amplifier 21 is +45 degrees, and the phase of the fundamental wave at the input terminal 402, after passing through the phase shift circuit 23, becomes 0 degrees. Furthermore, the phase of the fundamental wave of the second output signal at the node n2 output from the power amplifier 31 is −45 degrees, and the phase of the fundamental wave at the input terminal 403, after passing through the phase shift circuit 33, becomes 0 degrees. Thus, the fundamental wave signals in the first band are combined in an in-phase manner at the in-phase combiner 41 and output as a third output signal from the output terminal 401. Accordingly, the amplifier circuit 1 operates as a balanced amplifier that is resistant to changes in the load.

Meanwhile, the phase of a second-order harmonic wave of the first output signal at the node n1 output from the power amplifier 21 is +135 degrees (or +90+X degrees), and the phase of the second-order harmonic wave at the input terminal 402, after passing through the phase shift circuit 23, becomes +90 degrees. Furthermore, the phase of a second-order harmonic wave of a second output signal at the node n2 output from the power amplifier 31 is −135 degrees (or −90−Y degrees), and the phase of the second-order harmonic wave at the input terminal 403, after passing through the phase shift circuit 33, becomes −90 degrees. Thus, the second-order harmonic waves in the first band have a phase difference of 180 degrees (anti-phase relationship) between the input terminals 402 and 403 of the in-phase combiner 41 and are canceled. Therefore, since the second-order harmonic waves are suppressed, the quality of transmission signals and power efficiency can be improved in the amplifier circuit 1.

Furthermore, since each of the power amplifier circuits 20 and 30 in this embodiment is not a class-F amplifier in which the load impedance of even-order harmonic waves is short-circuited and the load impedance of odd-order harmonic waves is open and it is simply required that load impedances of second-order harmonic waves are divided into being inductive and being capacitive, the second-order harmonic waves can be canceled with high accuracy over, for example, the entire range of a wide band defined by 3GPP and a high transmission quality and a high power efficiency can be ensured.

In the amplifier circuit 1 according to this embodiment, a first phase shift difference (90 degrees or (+X+Y degrees)) obtained by subtracting the pass phase (−45 degrees or (−Y degrees)) of the harmonic wave of the harmonic wave phase shift circuit 32 from the pass phase (+45 degrees or (+X degrees)) of the harmonic wave of the harmonic wave phase shift circuit 22 is equal to a second phase shift difference (90 degrees (or +Y+X degrees)) obtained by subtracting the pass phase (−45 degrees (or −X degrees)) of the harmonic wave of the phase shift circuit 23 from the pass phase (+45 degrees (or +Y degrees)) of the harmonic wave of the phase shift circuit 33.

Thus, the second-order harmonic waves in the first band have a phase difference of 180 degrees (anti-phase relationship) between the input terminals 402 and 403 of the in-phase combiner 41 and are canceled. Therefore, since the second-order harmonic waves are suppressed, the quality of transmission signals and power efficiency can be improved in the amplifier circuit 1.

Furthermore, since it is simply required that the second-order harmonic waves in the first band have a phase difference of 180 degrees between the input terminals 402 and 403 of the in-phase combiner 41, the second-order harmonic waves can be canceled with high accuracy over the entire range of a wide band and a high transmission quality and a high power efficiency can be ensured.

In the amplifier circuit 1 according to this embodiment, the phase difference obtained by subtracting the phase of the second-order harmonic wave in the first band at the input terminal 403 from the phase of the second-order harmonic wave in the first band at the input terminal 402 should be larger than 90 degrees.

Thus, compared to the amplifier circuit 500 according to the comparative example, the second-order harmonic waves in the first band can be suppressed. Accordingly, compared to a conventional balanced amplifier in which a harmonic wave phase shift circuit is not additionally provided, the quality of transmission signals and power efficiency can be improved.

Next, specific circuit configurations of the harmonic wave phase shift circuits 22 and 32 and the phase shift circuits 23 and 33 in this embodiment will be described.

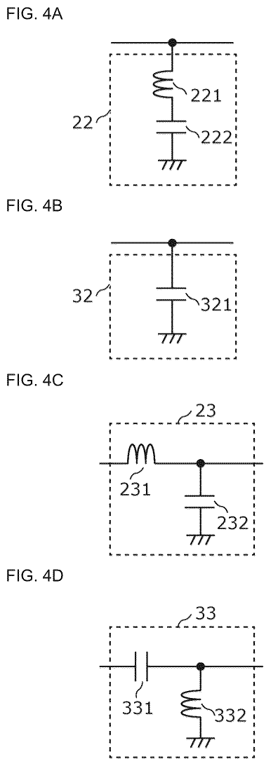

FIG. 4A is a diagram illustrating an example of the circuit configuration of the harmonic wave phase shift circuit 22 in this embodiment. As illustrated in the drawing, the harmonic wave phase shift circuit 22 includes, for example, an inductor 221 and a capacitor 222. The inductor 221 (third inductor) and the capacitor 222 (third capacitor) are connected in series to form an LC circuit, and the LC circuit is connected between a path connecting the fourth output end to an inductor 231 of the phase shift circuit 23 and the ground. The harmonic wave phase shift circuit 22 serves as a notch filter in which a fundamental wave band of the first band serves as a pass band and a second-order harmonic wave band serves as an attenuation band. The pass phase of the fundamental wave is, for example, 0 degrees, and the pass phase of the second-order harmonic wave is, for example, +45 degrees (+X degrees: X>0).

FIG. 4B is a diagram illustrating an example of the circuit configuration of the harmonic wave phase shift circuit 32 in this embodiment. As illustrated in the drawing, the harmonic wave phase shift circuit 32 includes, for example, a capacitor 321 (fourth capacitor) that is connected between a path connecting the fifth output end to a capacitor 331 of the phase shift circuit 33 and the ground. The harmonic wave phase shift circuit 32 serves as a low pass filter in which a fundamental wave band of the first band serves as a pass band and a second-order harmonic wave band serves as an attenuation band. The pass phase of the fundamental wave is, for example, 0 degrees, and the pass phase of the second-order harmonic wave is, for example, −45 degrees (−Y degrees: Y>0).

FIG. 4C is a diagram illustrating an example of the circuit configuration of the phase shift circuit 23 in this embodiment. As illustrated in the drawing, the phase shift circuit 23 includes, for example, the inductor 231 and a capacitor 232. The inductor 231 is an example of a first inductor and is connected between the fourth output end and the second input end. The capacitor 232 is an example of a first capacitor and is connected between a path connecting the inductor 231 to the second input end and the ground. The phase shift circuit 23 has a configuration of a low pass filter in which a fundamental wave band and a second-order harmonic wave band of the first band serve as a pass band. The pass phase of the fundamental wave in the first band is, for example, −45 degrees, and the pass phase of the second-order harmonic wave is, for example, −45 degrees (−X degrees).

FIG. 4D is a diagram illustrating an example of the circuit configuration of the phase shift circuit 33 in this embodiment. As illustrated in the drawing, the phase shift circuit 33 includes, for example, the capacitor 331 and an inductor 332. The capacitor 331 is an example of a second capacitor and is connected between the fifth output end and the third input end. The inductor 332 is an example of a second inductor and is connected between a path connecting the capacitor 331 to the third input end and the ground. The phase shift circuit 33 has a configuration of a high pass filter in which a fundamental wave band and a second-order harmonic wave band of the first band serve as a pass band. The pass phase of the fundamental wave in the first band is, for example, +45 degrees, and the pass phase of the second-order harmonic wave is, for example, +45 degrees (+Y degrees).

The phase shift circuits 23 and 33 and the harmonic wave phase shift circuits 22 and 32 may be included in a single semiconductor IC.

Accordingly, since the size of the amplifier circuit 1 can be reduced and the length of a signal wire from the power amplifiers 21 and 31 to the in-phase combiner 41 can be reduced, loss in signal transmission in the amplifier circuit 1 can be reduced.

### 2 Configuration of Amplifier Circuit 1A According to First Modification

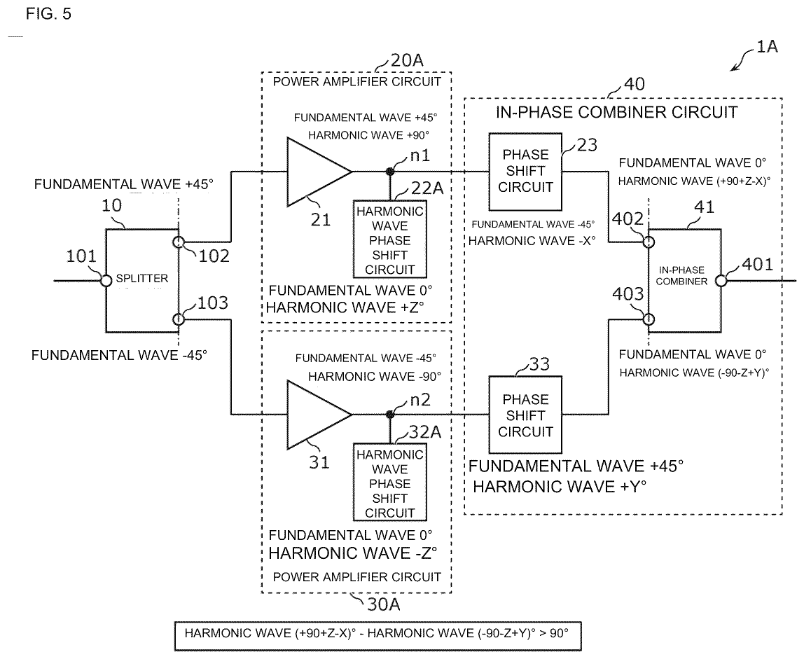

Next, an amplifier circuit 1A according to a first modification of the embodiment will be described. FIG. 5 is a circuit configuration diagram of the amplifier circuit 1A according to the first modification of the embodiment. As illustrated in the drawing, the amplifier circuit 1A includes a splitter 10, power amplifier circuits 20A and 30A, and an in-phase combiner circuit 40. The amplifier circuit 1A according to this modification is different from the amplifier circuit 1 according to the embodiment in the configurations of the power amplifier circuits 20A and 30A. Description of configuration features of the amplifier circuit 1A according to this modification that are the same as those of the amplifier circuit 1 according to the embodiment will be omitted, and different configuration features will be mainly described below.

The power amplifier circuit 20A is an example of a first power amplifier circuit and includes a power amplifier 21. The power amplifier 21 has the same configuration as the configuration of the power amplifier 21 in the embodiment. The power amplifier circuit 20A includes a harmonic wave phase shift circuit 22A, in addition to the power amplifier 21. The harmonic wave phase shift circuit 22A is an example of a first harmonic wave phase shift circuit. The harmonic wave phase shift circuit 22A is connected to a path connecting the fourth output end of the power amplifier 21 to the in-phase combiner 41 and shifts the phase of a harmonic wave in the first band. The harmonic wave phase shift circuit 22A does not considerably shift the phase of a fundamental wave in the first band. In this modification, the pass phase of the second-order harmonic wave of the harmonic wave phase shift circuit 22A is +Z degrees (Z>0).

The power amplifier circuit 30A is an example of a second power amplifier circuit and includes a power amplifier 31. The power amplifier 31 has the same configuration as the configuration of the power amplifier 31 in the embodiment. The power amplifier circuit 30A includes a harmonic wave phase shift circuit 32A, in addition to the power amplifier 31. The harmonic wave phase shift circuit 32A is an example of a second harmonic wave phase shift circuit. The harmonic wave phase shift circuit 32A is connected to a path connecting the fifth output end of the power amplifier 31 to the in-phase combiner 41 and shifts the phase of a harmonic wave in the first band. The harmonic wave phase shift circuit 32A does not considerably shift the phase of a fundamental wave in the first band. In this modification, the pass phase of the second-order harmonic wave of the harmonic wave phase shift circuit 32A is −Z degrees (Z>0).

The phase shift circuit 23 is an example of a first phase shift circuit. The phase shift circuit 23 is connected between the power amplifier circuit 20A and the in-phase combiner 41 and is configured to shift the phases of the fundamental wave and the harmonic wave in the first band. In this modification, the pass phase of the fundamental wave of the phase shift circuit 23 is −45 degrees, and the pass phase of the second-order harmonic wave is −X degrees (X>0).

The phase shift circuit 33 is an example of a second phase shift circuit. The phase shift circuit 33 is connected between the power amplifier circuit 30A and the in-phase combiner 41 and is configured to shift the phases of the fundamental wave and the harmonic wave in the first band in such a manner that the pass phase of the fundamental wave in the first band is +90 degrees relative to that of the phase shift circuit 23. In this modification, the pass phase of the fundamental wave of the phase shift circuit 33 is +45 degrees, and the pass phase of the second-order harmonic wave is +Y degrees (Y>0).

With the configuration of the amplifier circuit 1A according to this modification described above, the phase of a fundamental wave of a first output signal at the node n1 output from the power amplifier 21 is +45 degrees, and the phase of the fundamental wave at the input terminal 402, after passing through the phase shift circuit 23, becomes 0 degrees. Furthermore, the phase of a fundamental wave of a second output signal at the node n2 output from the power amplifier 31 is −45 degrees, and the phase of the fundamental wave at the input terminal 403, after passing through the phase shift circuit 33, becomes 0 degrees. Thus, the fundamental wave signals in the first band are combined in an in-phase manner at the in-phase combiner 41 and output as a third output signal from the output terminal 401. Accordingly, the amplifier circuit 1A operates as a balanced amplifier that is resistant to changes in the load.

In contrast, the phase of a second-order harmonic wave of the first output signal at the node n1 output from the power amplifier 21 is +90+Z degrees, and the phase of the second-order harmonic wave at the input terminal 402, after passing through the phase shift circuit 23, becomes +90+Z-X degrees. Furthermore, the phase of a second-order harmonic wave of the second output signal at the node n2 output from the power amplifier 31 is −90−Z degrees, and the phase of the second-order harmonic wave at the input terminal 403, after passing through the phase shift circuit 33, becomes −90−Z+Y degrees. Thus, the second-order harmonic waves in the first band have a phase difference of (+90+Z−X)−(−90−Z+Y)=180+2Z−X−Y between the input terminals 402 and 403 of the in-phase combiner 41. This phase difference is larger than 90 degrees.

Thus, compared to the amplifier circuit 500 according to the comparative example, the second-order harmonic waves in the first band can be suppressed. Therefore, since the second-order harmonic waves are suppressed, the quality of transmission signals and power efficiency can be improved compared to a conventional balanced amplifier in which a harmonic wave phase shift circuit is not additionally provided.

### 3 Configuration of Amplifier Circuit 1B According to Second Modification

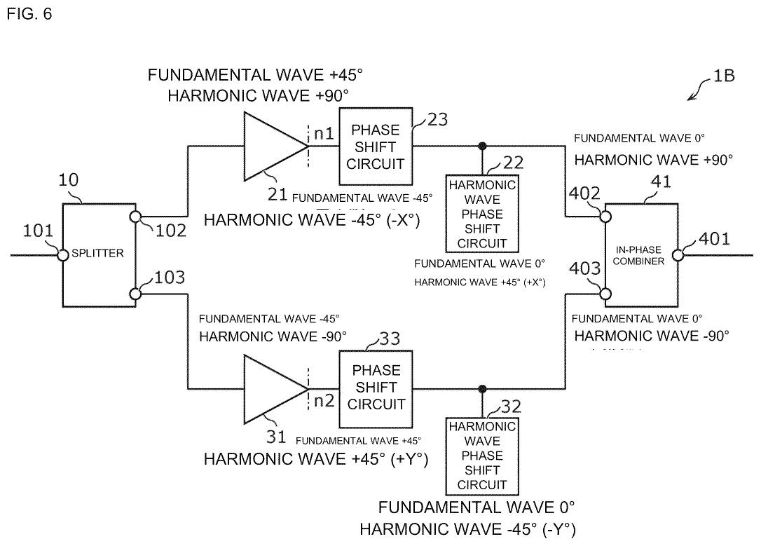

Next, an amplifier circuit 1B according to a second modification of the embodiment will be described. FIG. 6 is a circuit configuration diagram of the amplifier circuit 1B according to the second modification of the embodiment. As illustrated in the drawing, the amplifier circuit 1B includes a splitter 10, power amplifiers 21 and 31, harmonic wave phase shift circuits 22 and 32, phase shift circuits 23 and 33, and an in-phase combiner 41. The amplifier circuit 1B according to this modification is different from the amplifier circuit 1 according to the embodiment in the connection arrangement of the harmonic wave phase shift circuits and the phase shift circuits. Description of configuration features of the amplifier circuit 1B according to this modification that are the same as those of the amplifier circuit 1 according to the embodiment will be omitted, and different configuration features will be mainly described below.

The phase shift circuit 23 is an example of a first phase shift circuit. The phase shift circuit 23 is connected between the power amplifier 21 and the in-phase combiner 41 and is configured to shift phases of a fundamental wave and a harmonic wave in the first band. In this modification, the pass phase of the fundamental wave of the phase shift circuit 23 is −45 degrees, and the pass phase of the second-order harmonic wave is −45 degrees (or −X degrees: X>0).

The phase shift circuit 33 is an example of a second phase shift circuit. The phase shift circuit 33 is connected between the power amplifier 31 and the in-phase combiner 41 and is configured to shift the phases of the fundamental wave and the harmonic wave in the first band in such a manner that the pass phase of the fundamental wave in the first band is +90 degrees relative to that of the phase shift circuit 23. In this modification, the pass phase of the fundamental wave of the phase shift circuit 33 is +45 degrees, and the pass phase of the second-order harmonic wave is +45 degrees (or +Y degrees: Y>0).

The harmonic wave phase shift circuit 22 is an example of a first harmonic wave phase shift circuit. The harmonic wave phase shift circuit 22 is connected to a path connecting the phase shift circuit 23 to the in-phase combiner 41 and shifts the phase of the harmonic wave in the first band. The harmonic wave phase shift circuit 22 does not considerably shift the phase of the fundamental wave in the first band. In this modification, the pass phase of the second-order harmonic wave of the harmonic wave phase shift circuit 22 is +45 degrees (or +X degrees: X>0).

The harmonic wave phase shift circuit 32 is an example of a second harmonic wave phase shift circuit. The harmonic wave phase shift circuit 32 is connected to a path connecting the phase shift circuit 33 to the in-phase combiner 41 and shifts the phase of the harmonic wave in the first band. The harmonic wave phase shift circuit 32 does not considerably shift the phase of the fundamental wave in the first band. In this modification, the pass phase of the second-order harmonic wave of the harmonic wave phase shift circuit 32 is −45 degrees (or −Y: Y>0).

With the configuration of the amplifier circuit 1B according to this modification described above, the phase of a fundamental wave of a first output signal at the fourth output end (node n1) of the power amplifier 21 is +45 degrees, and the phase of the fundamental wave at the input terminal 402, after passing through the phase shift circuit 23 and the harmonic wave phase shift circuit 22, becomes 0 degrees. Furthermore, the phase of a fundamental wave of a second output signal at the fifth output end (node n2) of the power amplifier 31 is −45 degrees, and the phase of the fundamental wave at the input terminal 403, after passing through the phase shift circuit 33 and the harmonic wave phase shift circuit 32, becomes 0 degrees. Thus, the fundamental wave signals in the first band are combined in an in-phase manner at the in-phase combiner 41 and output as a third output signal from the output terminal 401. Accordingly, the amplifier circuit 1B operates as a balanced amplifier that is resistant to changes in the load.

In contrast, the phase of a second-order harmonic wave of the first output signal at the node n1 output from the power amplifier 21 is +90 degrees, and the phase of the second-order harmonic wave at the input terminal 402, after passing through the phase shift circuit 23 and the harmonic wave phase shift circuit 22, becomes +90 degrees. Furthermore, the phase of a second-order harmonic wave of the second output signal at the node n2 output from the power amplifier 31 is −90 degrees, and the phase of the second-order harmonic wave at the input terminal 403, after passing through the phase shift circuit 33 and the harmonic wave phase shift circuit 32, becomes −90 degrees. Thus, the second-order harmonic waves in the first band have a phase difference of 180 degrees (anti-phase relationship) between the input terminals 402 and 403 of the in-phase combiner 41 and are canceled. Therefore, since the second-order harmonic waves are suppressed, the quality of transmission signals and power efficiency can be improved in the amplifier circuit 1B.

In the amplifier circuit 1B according to this modification, the power amplifier 21, the phase shift circuit 23, and the harmonic wave phase shift circuit 22 are connected in this order. Thus, the impedance of the second-order harmonic wave assuming the in-phase combiner 41 side is seen from the fourth output end (node n1) of the power amplifier 21 is not inductive, and the power amplifier 21 does not serve as an inverse class-E amplifier. Furthermore, since the power amplifier 31, the phase shift circuit 33, and the harmonic wave phase shift circuit 32 are connected in this order, the impedance of the second-order harmonic wave assuming the in-phase combiner 41 side is seen from the fifth output end (node n2) of the power amplifier 31 is not capacitive, and the power amplifier 31 does not serve as a class-E amplifier.

### 4 Configuration of Amplifier Circuit 1C According to Third Modification

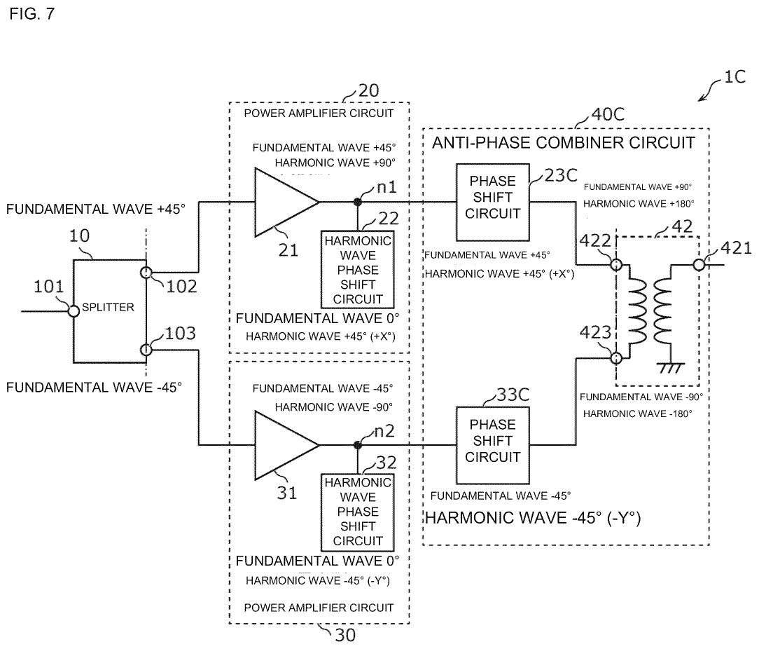

Next, an amplifier circuit 1C according to a third modification of the embodiment will be described. FIG. 7 is a circuit configuration diagram of the amplifier circuit 1C according to the third modification of the embodiment. As illustrated in the drawing, the amplifier circuit 1C includes a splitter 10, power amplifier circuits 20 and 30, and an anti-phase combiner circuit 40C. The amplifier circuit 1C according to this modification is different from the amplifier circuit 1 according to the embodiment in the configuration of a combiner circuit. Description of configuration features of the amplifier circuit 1C according to this modification that are the same as those of the amplifier circuit 1 according to the embodiment will be omitted, and different configuration features will be mainly described below.

The anti-phase combiner circuit 40C is an example of a combiner circuit and is configured to combine in an anti-phase manner a first output signal output from the power amplifier circuit 20 and a second output signal output from the power amplifier circuit 30. The anti-phase combiner circuit 40C includes a transformer 42 and phase shift circuits 23C and 33C.

The transformer 42 includes an input terminal 422 (second input end), which is one end of a primary side coil, an input terminal 423 (third input end), which is the other end of the primary side coil, and an output terminal 421 (third output end), which is one end of a secondary side coil that is electromagnetically coupled to the primary side coil. The other end of the secondary side coil is connected to the ground. With the configuration described above, the transformer 42 is configured to output from the output terminal 421 a third output signal generated by combining in an anti-phase manner the first output signal from the power amplifier circuit 20 input through the input terminal 422 and the second output signal from the power amplifier circuit 30 input through the input terminal 423.

The phase shift circuit 23C is an example of a first phase shift circuit. The phase shift circuit 23C is connected between the power amplifier circuit 20 and the transformer 42 and is configured to shift phases of a fundamental wave and a harmonic wave in the first band. In this modification, the pass phase of the fundamental wave of the phase shift circuit 23C is +45 degrees, and the pass phase of the second-order harmonic wave is +45 degrees.

The phase shift circuit 33C is an example of a second phase shift circuit. The phase shift circuit 33C is connected between the power amplifier circuit 30 and the transformer 42 and is configured to shift the phases of the fundamental wave and the harmonic wave in the first band in such a manner that the pass phase of the fundamental wave in the first band is −90 degrees relative to that of the phase shift circuit 23C. In this modification, the pass phase of the fundamental wave of the phase shift circuit 33C is −45 degrees, and the pass phase of the second-order harmonic wave is −45 degrees.

The pass phase of the second-order harmonic wave of the harmonic wave phase shift circuit 22 may be +X degrees (X>0), and the pass phase of the second-order harmonic wave of the phase shift circuit 23C may be +X degrees (X>0).

Furthermore, the pass phase of the second-order harmonic wave of the harmonic wave phase shift circuit 32 may be −Y degrees (Y>0), and the pass phase of the second-order harmonic wave of the phase shift circuit 33C may be −Y degrees (Y>0).

In the amplifier circuit 1C according this modification, since the pass phase of the second-order harmonic wave of the harmonic wave phase shift circuit 22 is +45 degrees (+X degrees), the impedance of the second-order harmonic wave assuming the anti-phase combiner circuit 40C side is seen from the connection point (node n1) between the fourth output end of the power amplifier 21 and the harmonic wave phase shift circuit 22 is located in the region of an inductive reactance (inductive impedance). In contrast, since the pass phase of the second-order harmonic wave of the harmonic wave phase shift circuit 32 is −45 degrees (−Y degrees), the impedance of the second-order harmonic wave assuming the anti-phase combiner circuit 40C side is seen from the connection point (node n2) between the fifth output end of the power amplifier 31 and the harmonic wave phase shift circuit 32 is located in the region of a capacitive reactance (capacitive impedance).

That is, in the amplifier circuit 1C according to this modification, the power amplifier circuit 20 serves as an inverse class-E amplifier that makes the load impedance inductive with respect to the second-order harmonic wave, and the power amplifier circuit 30 serves as a class-E amplifier that makes the load impedance capacitive with respect to the second-order harmonic wave.

In other words, there is a phase difference of 90 degrees (or X+Y degrees) between the phase of the impedance with respect to the second-order harmonic wave at the node n1 of the power amplifier circuit 20 and the phase of the impedance with respect to the second-order harmonic wave at the node n2 of the power amplifier circuit 30.

With the configuration of the amplifier circuit 1C according to this modification described above, the phase of the fundamental wave of the first output signal at the node n1 output from the power amplifier 21 is +45 degrees, and the phase of the fundamental wave at the input terminal 422, after passing through the phase shift circuit 23C, becomes +90 degrees. Furthermore, the phase of the fundamental wave of the second output signal at the node n2 output from the power amplifier 31 is −45 degrees, and the phase of the fundamental wave at the input terminal 423, after passing through the phase shift circuit 33C, becomes −90 degrees. Thus, the fundamental wave signals in the first band are combined in an anti-phase manner at the transformer 42 and output as the third output signal from the output terminal 421. Accordingly, the amplifier circuit 1C operates as a balanced amplifier that is resistant to changes in the load.

In contrast, the phase of the second-order harmonic wave of the first output signal at the node n1 output from the power amplifier 21 is +135 degrees (or +90+X degrees), and the phase of the second-order harmonic wave at the input terminal 422, after passing through the phase shift circuit 23C, becomes +180 degrees. Furthermore, the phase of the second-order harmonic wave of the second output signal at the node n2 output from the power amplifier 31 is −135 degrees (or −90−Y degrees), and the phase of the second-order harmonic wave at the input terminal 423, after passing through the phase shift circuit 33C, becomes −180 degrees. Thus, the second-order harmonic waves in the first band have a phase difference of 360 degrees (in-phase relationship) between the input terminals 422 and 423 of the transformer 42 and are canceled. Therefore, since the second-order harmonic waves are suppressed, the quality of transmission signals and power efficiency can be improved in the amplifier circuit 1C.

Furthermore, since each of the power amplifier circuits 20 and 30 in this modification is not a class-F amplifier in which the load impedance of even-order harmonic waves is short-circuited and the load impedance of odd-order harmonic waves is open and it is simply required that load impedances of second-order harmonic waves are divided into being inductive and being capacitive, the second-order harmonic waves can be canceled with high accuracy over, for example, the entire range of a wide band defined by 3GPP and a high transmission quality and a high power efficiency can be ensured.

In the amplifier circuit 1C according to this modification, a first phase shift difference (90 degrees or (+X+Y degrees)) obtained by subtracting the pass phase (−45 degrees or (−Y degrees)) of the harmonic wave of the harmonic wave phase shift circuit 32 from the pass phase (+45 degrees or (+X degrees)) of the harmonic wave of the harmonic wave phase shift circuit 22 is equal to a second phase shift difference (90 degrees (or +Y+X degrees)) obtained by subtracting the pass phase (−45 degrees (or −Y degrees)) of the harmonic wave of the phase shift circuit 33C from the pass phase (+45 degrees (or +X degrees)) of the harmonic wave of the phase shift circuit 23C.

Accordingly, the second-order harmonic waves in the first band become in the in-phase relationship between the input terminals 422 and 423 of the transformer 42 and are canceled. Therefore, since the second-order harmonic waves are suppressed, the quality of transmission signals and power efficiency can be improved in the amplifier circuit 1C.

Furthermore, it is simply required that the second-order harmonic waves in the first band have a phase difference of 0 degrees (±360×m: m is a natural number) between the input terminals 422 and 423 of the transformer 42. Therefore, the second-order harmonic waves can be canceled with high accuracy over the entire range of a wide band, and a high transmission quality and a high power efficiency can be ensured.

In the amplifier circuit 1C according to this modification, the phase difference obtained by subtracting the phase of the second-order harmonic wave in the first band at the input terminal 423 from the phase of the second-order harmonic wave in the first band at the input terminal 422 should be smaller than 90 degrees.

Accordingly, since the second-order harmonic waves in the first band are suppressed, the quality of transmission signals and power efficiency can be improved compared to a conventional balanced amplifier of an anti-phase combining type in which a harmonic wave phase shift circuit is not additionally provided.

### 5 Configuration of Amplifier Circuit 1D According to Fourth Modification

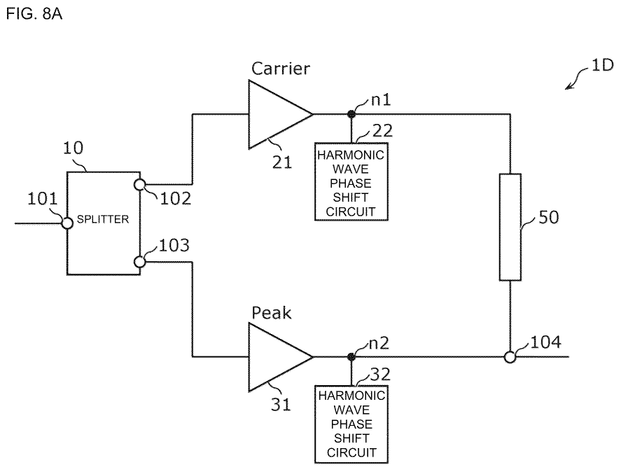

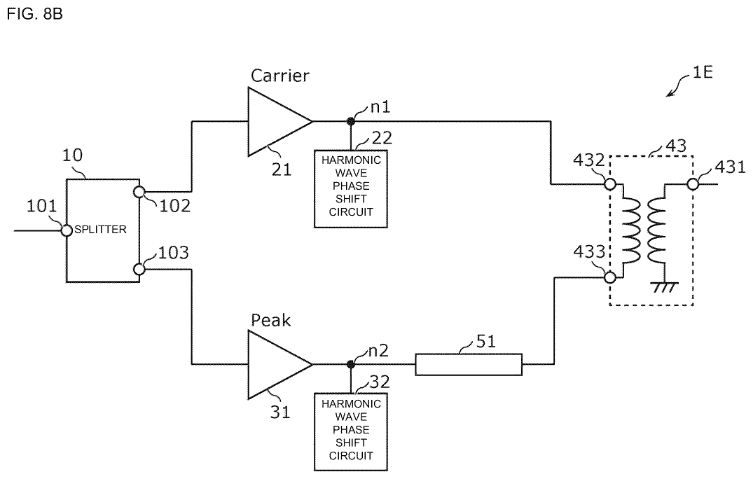

Next, an amplifier circuit 1D according to a fourth modification of the embodiment will be described. FIG. 8A is a circuit configuration diagram of the amplifier circuit 1D according to the fourth modification of the embodiment. As illustrated in the drawing, the amplifier circuit 1D includes a splitter 10, power amplifiers 21 and 31, harmonic wave phase shift circuits 22 and 32, and a phase shift line 50. The amplifier circuit 1D according to this modification is different in that the amplifier circuit 1D also operates as a Doherty amplifier. Description of configuration features of the amplifier circuit 1D according to this modification that are the same as those of the amplifier circuit 1 according to the embodiment will be omitted, and different configuration features will be mainly described below.

The splitter 10 includes an input terminal 101 (first input end), an output terminal 102 (first output end), and an output terminal 103 (second output end). The splitter 10 is configured to split a fundamental wave signal in a transmission band of a first band input to the input terminal 101, output from the output terminal 102 a first signal, and output from the output terminal 103 a second signal whose phase is −90 degrees (delayed by 90 degrees) relative to a phase of the first signal.

The power amplifier 21 is an example of a carrier amplifier and includes an amplifier transistor. The power amplifier 21 has a third input end and a fourth output end, and the third input end is connected to the output terminal 102 of the splitter 10.

The power amplifier 31 is an example of a peak amplifier and includes an amplifier transistor. The power amplifier 31 has a fourth input end and a fifth output end, and the fourth input end is connected to the output terminal 103 of the splitter 10.

The amplifier transistor in each of the power amplifiers 21 and 31 is, for example, a bipolar transistor such as an HBT or a field-effect transistor such as a MOSFET.

The power amplifier 21 amplifies a transmission signal in the first band input to the third input end thereof. The power amplifier 21 is, for example, a class-A (or class-AB) amplifier circuit that is capable of performing an amplifying operation for all the power levels of signals input to the power amplifier 21. In particular, the power amplifier 21 is capable of performing a highly efficient amplifying operation in a low output region and a medium output region.

The power amplifier 31 amplifies a transmission signal in the first band input to the fourth input end thereof. The power amplifier 31 is, for example, a class-C amplifier circuit that is capable of performing an amplifying operation in a region where the power level of signals input to the power amplifier 31 is high. A bias current smaller than a bias current applied to the amplifier transistor included in the power amplifier 21 may be applied to the amplifier transistor included in the power amplifier 31. Accordingly, as the power level of a signal input to the power amplifier 31 increases, the output impedance decreases. Thus, the power amplifier 31 is capable of performing a low-distortion amplifying operation in a high output region.

Since the power amplifier 21 amplifies the first signal output from the splitter 10 and the power amplifier 31 amplifies the second signal output from the splitter 10, the phase of a fundamental wave at the fifth output end of the power amplifier 31 is delayed by 90 degrees with respect to the phase of a fundamental wave at the fourth output end of the power amplifier 21.

The phase shift line 50 has a second input end and a third output end. The second input end is connected to the fourth output end, and the third output end is connected to the fifth output end with the output terminal 104 interposed therebetween. The phase shift line 50 is configured to delay a fundamental wave of a first output signal from the power amplifier 21 input through the second input end by 90 degrees. Due to the arrangement of the phase shift line 50, the phase of the fundamental wave of the first output signal output from the power amplifier 21 and the phase of a fundamental wave of a second output signal output from the power amplifier 31 are made to match. Accordingly, the fundamental wave of the first output signal and the fundamental wave of the second output signal are combined in an in-phase manner (current combining) at the output terminal 104. The phase shift line 50 and the output terminal 104 form a combiner circuit.

The harmonic wave phase shift circuit 22 is an example of a first harmonic wave phase shift circuit. The harmonic wave phase shift circuit 22 is connected to a path connecting the fourth output end of the power amplifier 21 to the second input end of the phase shift line 50 and shifts the phase of a harmonic wave in the first band. The harmonic wave phase shift circuit 22 does not considerably shift the phase of a fundamental wave in the first band. In this modification, the pass phase of the second-order harmonic wave of the harmonic wave phase shift circuit 22 is +45 degrees.

The harmonic wave phase shift circuit 32 is an example of a second harmonic wave phase shift circuit. The harmonic wave phase shift circuit 32 is connected to a path connecting the fifth output end of the power amplifier 31 to the output terminal 104 and shifts the phase of the harmonic wave in the first band. The harmonic wave phase shift circuit 32 does not considerably shift the phase of the fundamental wave in the first band. In this modification, the pass phase of the second-order harmonic wave of the harmonic wave phase shift circuit 32 is −45 degrees.

The pass phase of the second-order harmonic wave of the harmonic wave phase shift circuit 22 may be +X degrees (X>0), and the pass phase of the second-order harmonic wave of the harmonic wave phase shift circuit 32 may be −Y degrees (Y>0).

The power amplifier 21 and the harmonic wave phase shift circuit 22 form a first power amplifier circuit, and the power amplifier 31 and the harmonic wave phase shift circuit 32 form a second power amplifier circuit.

With the configuration of the amplifier circuit 1D described above, the output impedance of the power amplifier 21 at the time assuming a small signal is input is higher than that at the time assuming a large signal is input. That is, assuming a small signal is input, the power amplifier 31 enters an OFF state, and the output impedance of the power amplifier 21 increases. Thus, the amplifier circuit 1D can operate with high efficiency.

In contrast, assuming a large signal is input, operation of the power amplifiers 21 and 31 allows a large power signal to be output and a decrease in the output impedance of the power amplifier 31 allows signal distortion to be suppressed.

Furthermore, since the phase of the fundamental wave at the fifth output end of the power amplifier 31 is delayed by 90 degrees with respect to the phase of the fundamental wave at the fourth output end of the power amplifier 21, the phase of the second-order harmonic wave at the fifth output end of the power amplifier 31 is delayed by 180 degrees with respect to the phase of the second-order harmonic wave at the fourth output end of the power amplifier 21. In this modification, the phase of the second-order harmonic wave at the fourth output end of the power amplifier 21 is +90 degrees, and the phase of the second-order harmonic wave at the fifth output end of the power amplifier 31 is −90 degrees.

With the configuration of the amplifier circuit 1D according to this modification described above, the phase of the second-order harmonic wave of the first output signal at the connection point (node n1) between the fourth output end of the power amplifier 21 and the harmonic wave phase shift circuit 22 is +135 degrees (or +90+X degrees) and the phase of the second-order harmonic wave at the output terminal 104, after passing through the phase shift line 50, becomes +45 (or X degrees). Furthermore, the phase of the second-order harmonic wave of the second output signal at the node n2 output from the power amplifier 31 is −135 degrees (or −90−Y degrees), and the phase of the second-order harmonic wave at the output terminal 104 is −135 degrees (or −90−Y degrees). Accordingly, the second-order harmonic wave of the first output signal and the second-order harmonic wave of the second output signal have a phase difference of 180 degrees (anti-phase relationship) at the output terminal 104 and are canceled. Therefore, since the second-order harmonic waves are suppressed, the quality of transmission signals and power efficiency can be improved in the amplifier circuit 1D.

Furthermore, in the amplifier circuit 1D according to this modification, the first power amplifier circuit serves as an inverse class-E amplifier that makes the load impedance inductive with respect to the second-order harmonic wave and the second power amplifier circuit serves as a class-E amplifier that makes the load impedance capacitive with respect to the second-order harmonic wave.

Accordingly, the second-order harmonic waves can be canceled with high accuracy over, for example, the entire range of a wide band defined by 3GPP, and a high transmission quality and a high power efficiency can be ensured.

In the amplifier circuit 1D according to this modification, the phase difference obtained by subtracting the phase of the second-order harmonic wave of the second output signal at the output terminal 104 from the phase of the second-order harmonic wave of the first output signal at the output terminal 104 should be larger than 90 degrees.

Accordingly, since the second-order harmonic waves in the first band are suppressed, the quality of transmission signals and power efficiency can be improved compared to a conventional Doherty amplifier in which a harmonic wave phase shift circuit is not additionally provided.

### 6 Configuration of Amplifier Circuit 1E According to Fifth Modification

Next, an amplifier circuit 1E according to a fifth modification of the embodiment will be described. FIG. 8B is a circuit configuration diagram of the amplifier circuit 1E according to the fifth modification of the embodiment. As illustrated in the drawing, the amplifier circuit 1E includes a splitter 10, power amplifiers 21 and 31, harmonic wave phase shift circuits 22 and 32, a phase shift line 51, and a transformer 43. The amplifier circuit 1E according to this modification is different from the amplifier circuit 1D according to the fourth modification in the configuration of signal combining. Description of configuration features of the amplifier circuit 1E according to this modification that are the same as those of the amplifier circuit 1D according to the fourth modification will be omitted, and different configuration features will be mainly described below.

The transformer 43 includes an input terminal 432 (third input end), which is one end of a primary side coil, an input terminal 433 (fourth input end), which is the other end of the primary side coil, and an output terminal 431 (fourth output end), which is one end of a secondary side coil that is electromagnetically coupled to the primary side coil. The other end of the secondary side coil is connected to the ground. With the configuration described above, the transformer 43 is configured to output from the output terminal 431 a third output signal generated by combining in an anti-phase manner a first output signal from the power amplifier circuit 20 input through the input terminal 432 and a second output signal from the power amplifier circuit 30 input through the input terminal 433.

The phase shift line 51 has a second input end and a third output end and is configured to delay a fundamental wave of the second output signal from the power amplifier 31 input through the second input end by 90 degrees. Due to the arrangement of the phase shift line 51, the phase of a fundamental wave of the first output signal output from the power amplifier 21 and the phase of a fundamental wave of the second output signal output from the power amplifier 31 become opposite. Accordingly, the fundamental wave of the first output signal and the fundamental wave of the second output signal are combined in an anti-phase manner (voltage combining) at the transformer 43. The phase shift line 51 and the transformer 43 form a combiner circuit.

The power amplifier 21 is an example of a carrier amplifier and includes an amplifier transistor. The power amplifier 21 has a fifth input end and a fifth output end, the fifth input end is connected to the output terminal 102 of the splitter 10, and the fifth output end is connected to the input terminal 432.

The power amplifier 31 is an example of a peak amplifier and includes an amplifier transistor. The power amplifier 31 has a sixth input end and a sixth output end. The sixth input end is connected to the output terminal 103 of the splitter 10, and the sixth output end is connected to the second input end. Furthermore, the third output end is connected to the input terminal 433.

The power amplifier 21 amplifies a transmission signal in the first band input to the fifth input end thereof. The power amplifier 21 is, for example, a class-A (or class-AB) amplifier circuit that is capable of performing an amplifying operation for all the power levels of signals input to the power amplifier 21. In particular, the power amplifier 21 is capable of performing a highly efficient amplifying operation in a low output region and a medium output region.

The power amplifier 31 amplifies a transmission signal in the first band input to the sixth input end thereof. The power amplifier 31 is, for example, a class-C amplifier circuit that is capable of performing an amplifying operation in a region where the power level of signals input to the power amplifier 31 is high. A bias current smaller than a bias current applied to the amplifier transistor included in the power amplifier 21 may be applied to the amplifier transistor included in the power amplifier 31. Accordingly, as the power level of a signal input to the power amplifier 31 increases, the output impedance decreases. Thus, the power amplifier 31 is capable of performing a low-distortion amplifying operation in a high output region.

Since the power amplifier 21 amplifies a first signal output from the splitter 10 and the power amplifier 31 amplifies a second signal output from the splitter 10, the phase of the fundamental wave at the sixth output end of the power amplifier 31 is delayed by 90 degrees with respect to the phase of the fundamental wave at the fifth output end of the power amplifier 21.

The harmonic wave phase shift circuit 22 is an example of a first harmonic wave phase shift circuit. The harmonic wave phase shift circuit 22 is connected to a path connecting the fifth output end to the input terminal 432 and shifts the phase of a harmonic wave in the first band. The harmonic wave phase shift circuit 22 does not considerably shift the phase of the fundamental wave in the first band. In this modification, the pass phase of the second-order harmonic wave of the harmonic wave phase shift circuit 22 is +45 degrees.

The harmonic wave phase shift circuit 32 is an example of a second harmonic wave phase shift circuit. The harmonic wave phase shift circuit 32 is connected to a path connecting the sixth output end to the second input end and shifts the phase of the harmonic wave in the first band. The harmonic wave phase shift circuit 32 does not considerably shift the phase of the fundamental wave in the first band. In this modification, the pass phase of the second-order harmonic wave of the harmonic wave phase shift circuit 32 is −45 degrees.

The pass phase of the second-order harmonic wave of the harmonic wave phase shift circuit 22 may be +X degrees (X>0), and the pass phase of the second-order harmonic wave of the harmonic wave phase shift circuit 32 may be −Y degrees (Y>0).

The power amplifier 21 and the harmonic wave phase shift circuit 22 form a first power amplifier circuit, and the power amplifier 31 and the harmonic wave phase shift circuit 32 form a second power amplifier circuit.

With the configuration of the amplifier circuit 1E described above, the output impedance of the power amplifier 21 at the time assuming a small signal is input is higher than that at the time assuming a large signal is input. That is, assuming a small signal is input, the power amplifier 31 enters an OFF state, and the output impedance of the power amplifier 21 increases. Thus, the amplifier circuit 1E can operate with high efficiency.

In contrast, assuming a large signal is input, operation of the power amplifiers 21 and 31 allows a large power signal to be output and a decrease in the output impedance of the power amplifier 31 allows signal distortion to be suppressed.

Furthermore, since the phase of the fundamental wave at the sixth output end of the power amplifier 31 is delayed by 90 degrees with respect to the phase of the fundamental wave at the fifth output end of the power amplifier 21, the phase of the second-order harmonic wave at the sixth output end of the power amplifier 31 is delayed by 180 degrees with respect to the phase of the second-order harmonic wave at the fifth output end of the power amplifier 21. In this modification, the phase of the second-order harmonic wave at the fifth output end is +90 degrees, and the phase of the second-order harmonic wave at the sixth output end is −90 degrees.

With the configuration of the amplifier circuit 1E according to this modification described above, the phase of the second-order harmonic wave of the first output signal at the connection point (node n1) between the fifth output end of the power amplifier 21 and the harmonic wave phase shift circuit 22 is +135 degrees (or +90+X degrees), and the phase of the second-order harmonic wave at the input terminal 432 is +135 degrees (or +90+X degrees). Furthermore, the phase of the second-order harmonic wave of the second output signal at the connection point (node n2) between the sixth output end of the power amplifier 31 and the harmonic wave phase shift circuit 32 is −135 degrees (or −90−Y degrees), and the phase of the second-order harmonic wave at the input terminal 433, after passing through the phase shift line 51, becomes −225 degrees (or −135−Y degrees). Thus, the second-order harmonic wave of the first output signal and the second-order harmonic wave of the second output signal have a phase difference of 360 degrees (in-phase relationship) between the input terminals 432 and 433 of the transformer 43 and are canceled. Therefore, since the second-order harmonic waves are suppressed, the quality of transmission signals and power efficiency can be improved in the amplifier circuit 1E.

Furthermore, in the amplifier circuit 1E according to this modification, the first power amplifier circuit serves as an inverse class-E amplifier that makes the load impedance inductive with respect to the second-order harmonic wave, and the second power amplifier circuit serves as a class-E amplifier that makes the load impedance capacitive with respect to the second-order harmonic wave.

Accordingly, the second-order harmonic waves can be canceled with high accuracy over, for example, the entire range of a wide band defined by 3GPP, and a high transmission quality and a high power efficiency can be ensured.

In the amplifier circuit 1E according to this modification, the phase difference obtained by subtracting the phase of the second-order harmonic wave of the second output signal at the input terminal 433 from the phase of the second-order harmonic wave of the first output signal at the input terminal 432 should be smaller than 90 degrees.

Accordingly, since the second-order harmonic waves in the first band are suppressed, the quality of transmission signals and power efficiency can be improved compared to a conventional Doherty amplifier in which a harmonic wave phase shift circuit is not additionally provided.

### 7 Configuration of Amplifier Circuit 1F According to Sixth Modification

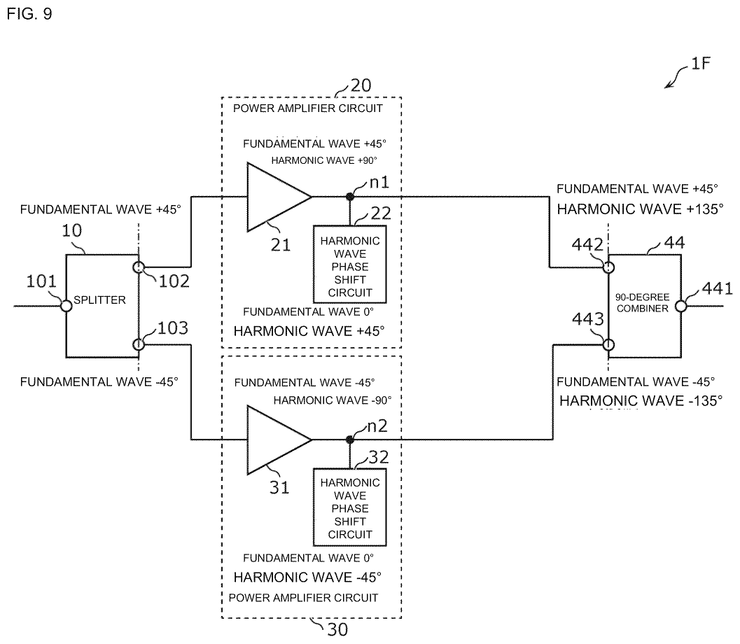

Next, an amplifier circuit 1F according to a sixth modification of the embodiment will be described. FIG. 9 is a circuit configuration diagram of the amplifier circuit 1F according to the sixth modification of the embodiment. As illustrated in the drawing, the amplifier circuit 1F includes a splitter 10, power amplifier circuits 20 and 30, and a 90-degree combiner 44. The amplifier circuit 1F according to this modification is different from the amplifier circuit 1 according to the embodiment in the configuration of a combiner circuit. Description of configuration features of the amplifier circuit 1F according to this modification that are the same as those of the amplifier circuit 1 according to the embodiment will be omitted, and different configuration features will be mainly described below.

The combiner circuit in this modification includes the 90-degree combiner 44 but includes no phase shift circuit. The 90-degree combiner 44 includes an input terminal 442 (second input end), an input terminal 443 (third input end), and an output terminal 441 (third output end) and is configured to output from the output terminal 441 a third output signal generated by combining a first output signal input through the input terminal 442 and a signal obtained by shifting the phase of a second output signal input through the input terminal 443 to become +90 degrees with respect to the phase of the first output signal.

With the amplifier circuit 1F according to this modification, since the pass phase of a second-order harmonic wave of the harmonic wave phase shift circuit 22 is +45 degrees, the impedance of the second-order harmonic wave assuming the 90-degree combiner 44 side is seen from the connection point (node n1) between the fourth output end of the power amplifier 21 and the harmonic wave phase shift circuit 22 is located in the region of an inductive reactance (inductive impedance). In contrast, since the pass phase of a second-order harmonic wave of the harmonic wave phase shift circuit 32 is −45 degrees, the impedance of the second-order harmonic wave assuming the 90-degree combiner 44 side is seen from the connection point (node n2) between the fifth output end of the power amplifier 31 and the harmonic wave phase shift circuit 32 is located in the region of a capacitive reactance (capacitive impedance).

That is, in the amplifier circuit 1F according to this modification, the power amplifier circuit 20 serves as an inverse class-E amplifier that makes the load impedance inductive with respect to the second-order harmonic wave, and the power amplifier circuit 30 serves as a class-E amplifier that makes the load impedance capacitive with respect to the second-order harmonic wave.

In other words, the phase of the impedance with respect to the second-order harmonic wave at the node n1 of the power amplifier circuit 20 and the phase of the impedance with respect to the second-order harmonic wave at the node n2 of the power amplifier circuit 30 have a phase difference of 90 degrees.

With the configuration of the amplifier circuit 1F according to this modification described above, the phase of a fundamental wave of the first output signal at the node n1 output from the power amplifier 21 is +45 degrees and the phase of the fundamental wave at the input terminal 442 is +45 degrees. Furthermore, the phase of a fundamental wave of the second output signal at the node n2 output from the power amplifier 31 is −45 degrees, and the phase of the fundamental wave at the input terminal 443 is −45 degrees. Thus, the fundamental wave signals in the first band are combined in an in-phase manner at the 90-degree combiner 44 and output as the third output signal from the output terminal 441. Accordingly, the amplifier circuit 1F operates as a balanced amplifier that is resistant to changes in the load.

In contrast, the phase of the second-order harmonic wave of the first output signal at the node n1 output from the power amplifier 21 is +135 degrees, and the phase of the second-order harmonic wave at the input terminal 442 is +135 degrees. Furthermore, the phase of the second-order harmonic wave of the second output signal at the node n2 output from the power amplifier 31 is −135 degrees, and the phase of the second-order harmonic wave at the input terminal 443 is −135 degrees. Thus, the second-order harmonic waves in the first band have a phase difference of 270 degrees between the input terminals 442 and 443, and the phase difference becomes 180 degrees at the 90-degree combiner 44 and is canceled out. Therefore, since the second-order harmonic waves are suppressed, the quality of transmission signals and power efficiency can be improved in the amplifier circuit 1F.

Furthermore, since each of the power amplifier circuits 20 and 30 in this modification is not a class-F amplifier in which the load impedance of even-order harmonic waves is short-circuited and the load impedance of odd-order harmonic waves is open and it is simply required that load impedances of second-order harmonic waves are divided into being inductive and being capacitive, the second-order harmonic waves can be canceled with high accuracy over, for example, the entire range of a wide band defined by 3GPP and a high transmission quality and a high power efficiency can be ensured.

### 8 Effects and Others

As described above, the amplifier circuit 1 according to this embodiment (the amplifier circuit 1A according to the first modification and the amplifier circuit 1D according to the fourth modification) includes the power amplifier circuit 20 (20A) that includes the power amplifier 21, the power amplifier circuit 30 (30A) that includes the power amplifier 31 in which the phase of a fundamental wave at an output end thereof is delayed by 90 degrees with respect to the power amplifier 21, and the in-phase combiner circuit 40 (phase shift line 50) that is configured to combine a fundamental wave of a first output signal output from the power amplifier circuit 20 (20A) and a fundamental wave of a second output signal output from the power amplifier circuit 30 (30A). The power amplifier circuit 20 (20A) is of an inverse class-E type, and the power amplifier circuit 30 (30A) is of a class-E type.

Accordingly, since the power amplifier circuits 20 (20A) and 30 (30A) are not class-F amplifiers in which the load impedance of even-order harmonic waves is short-circuited and the load impedance of odd-order harmonic waves is open but are an inverse class-E amplifier and a class-E amplifier, respectively, in which load impedances of second-order harmonic waves are divided into being inductive and being capacitive, the second-order harmonic waves can be canceled with high accuracy over, for example, the entire range of a wide band defined by 3GPP. Thus, the amplifier circuit can function as a balanced amplifier that is resistant to changes in the load, and a high transmission quality and a high power efficiency can be ensured.

Furthermore, for example, the amplifier circuit 1 (1A) further includes the splitter 10 that includes the input terminal 101 and the output terminals 102 and 103 and is configured to split a fundamental wave signal in a transmission band of the first band input to the input terminal 101, output from the output terminal 102 a first signal, and output from the output terminal 103 a second signal whose phase is −90 degrees with respect to a phase of the first signal. The in-phase combiner circuit 40 includes the in-phase combiner 41 that includes the input terminals 402 and 403 and the output terminal 401 and is configured to output from the output terminal 401 a third output signal generated by combining in an in-phase manner the first output signal from the power amplifier circuit 20 (20A) input through the input terminal 402 and the second output signal from the power amplifier circuit 30 (30A) input through the input terminal 403, the phase shift circuit 23 that is connected between the power amplifier circuit 20 (20A) and the in-phase combiner 41 and is configured to shift phases of a fundamental wave and a second-order harmonic wave in the first band, and the phase shift circuit 33 that is connected between the power amplifier circuit 30 (30A) and the in-phase combiner 41 and is configured to shift the phases of the fundamental wave and a second-order harmonic wave in the first band in such a manner that the pass phase of the fundamental wave is +90 degrees with respect to the phase shift circuit 23. The power amplifier circuit 20 (20A) includes the power amplifier 21 that has the fourth input end and the fourth output end, the fourth input end being connected to the output terminal 102, and the harmonic wave phase shift circuit 22 that is connected to a path connecting the fourth output end to the input terminal 402 and is configured to shift the phase of the second-order harmonic wave. The power amplifier circuit 30 (30A) includes the power amplifier 31 that has the fifth input end and the fifth output end, the fifth input end being connected to the output terminal 103, and the harmonic wave phase shift circuit 32 that is connected to a path connecting the fifth output end to the input terminal 403 and is configured to shift the phase of the second-order harmonic wave. A phase shift difference obtained by subtracting the phase of the second-order harmonic wave at the input terminal 403 from the phase of the second-order harmonic wave at the input terminal 402 is larger than 90 degrees.

Accordingly, compared to a conventional balanced amplifier of an in-phase combining type in which a harmonic wave phase shift circuit is not additionally provided, the second-order harmonic waves in the first band can be suppressed over a wide range. Therefore, the quality of transmission signals and power efficiency can be improved.

Furthermore, for example, in the amplifier circuit 1, a first phase shift difference obtained by subtracting the pass phase of the second-order harmonic wave of the harmonic wave phase shift circuit 32 from the pass phase of the second-order harmonic wave of the harmonic wave phase shift circuit 22 is equal to a second phase shift difference obtained by subtracting the pass phase of the second-order harmonic wave of the phase shift circuit 23 from the pass phase of the second-order harmonic wave of the phase shift circuit 33.

Accordingly, the second-order harmonic waves in the first band have a phase difference of 180 degrees (anti-phase relationship) between the input terminals 402 and 403 of the in-phase combiner 41 and are canceled. Thus, the amplifier circuit 1 in which the quality of transmission signals and power efficiency are improved can be provided.

Furthermore, for example, in the amplifier circuit 1, the phase shift circuit 23 is configured in such a manner that the pass phases of the fundamental wave and the second-order harmonic wave are −45 degrees, the phase shift circuit 33 is configured in such a manner that the pass phases of the fundamental wave and the second-order harmonic wave are +45 degrees, the harmonic wave phase shift circuit 22 is configured in such a manner that the pass phase of the harmonic wave is +45 degrees, and the harmonic wave phase shift circuit 32 is configured in such a manner that the pass phase of the harmonic wave is −45 degrees.

Accordingly, the second-order harmonic waves in the first band have a phase difference of 180 degrees (anti-phase relationship) between the input terminals 402 and 403 of the in-phase combiner 41 and are canceled. Thus, the amplifier circuit 1 in which the quality of transmission signals and power efficiency are improved can be provided.

Furthermore, for example, in the amplifier circuit 1, the phase shift circuit 23 is configured in such a manner that the pass phase of the fundamental wave is −45 degrees and the pass phase of the harmonic wave is −X degrees (X>0), the phase shift circuit 33 is configured in such a manner that the pass phase of the fundamental wave is +45 degrees and the pass phase of the harmonic wave is +Y degrees (Y>0), the harmonic wave phase shift circuit 22 is configured in such a manner that the pass phase of the harmonic wave is +X degrees (X>0), and the harmonic wave phase shift circuit 32 is configured in such a manner that the pass phase of the harmonic wave is −Y degrees (Y>0).

Accordingly, the second-order harmonic waves in the first band have a phase difference of 180 degrees (anti-phase relationship) between the input terminals 402 and 403 of the in-phase combiner 41 and are canceled. Thus, the amplifier circuit 1 in which the quality of transmission signals and power efficiency are improved can be provided.

Furthermore, for example, the amplifier circuit 1D according to the fourth modification further includes the splitter 10 that includes the input terminal 101 and the output terminals 102 and 103 and is configured to split a fundamental wave signal in a transmission band of the first band input to the input terminal 101, output from the output terminal 102 a first signal, and output from the output terminal 103 a second signal whose phase is −90 degrees with respect to a phase of the first signal. The combiner circuit includes the phase shift line 50 that has the second input end and the third output end and is configured to delay the fundamental wave of the first output signal from the first power amplifier circuit input through the second input end by 90 degrees. The first power amplifier circuit includes a carrier amplifier (power amplifier 21) that has the third input end and the fourth output end, the third input end being connected to the output terminal 102, the fourth output end being connected to the second input end, and the harmonic wave phase shift circuit 22 that is connected to a path connecting the fourth output end to the second input end and is configured to shift a phase of a second-order harmonic wave in the first band. The second power amplifier circuit includes a peak amplifier (power amplifier 31) that has the fourth input end and the fifth output end, the fourth input end being connected to the output terminal 103, the fifth output end being connected to the third output end, and the harmonic wave phase shift circuit 32 that is connected to a path connecting the fifth output end to the third output end and is configured to shift the phase of the second-order harmonic wave. A phase shift difference obtained by subtracting the phase of the second-order harmonic wave from the fifth output end input to the third output end from the phase of the second-order harmonic wave from the fourth output end input to the third output end is larger than 90 degrees.

Accordingly, compared to a conventional Doherty amplifier in which a harmonic wave phase shift circuit is not additionally provided, the second-order harmonic waves in the first band can be suppressed with high accuracy, and the quality of transmission signals and power efficiency can be improved.

Furthermore, for example, the amplifier circuit 1E according to the fifth modification further includes the splitter 10 that includes the input terminal 101 and the output terminals 102 and 103 and is configured to split a fundamental wave signal in a transmission band of the first band input to the input terminal 101, output from the output terminal 102 a first signal, and output from the output terminal 103 a second signal whose phase is −90 degrees with respect to a phase of the first signal. The combiner circuit includes the phase shift line 51 that has the second input end and the third output end and is configured to delay the fundamental wave of the second output signal input through the second input end by 90 degrees, and the transformer 43 that has the input terminals 432 and 433 and the output terminal 431 and is configured to output from the output terminal 431 a third output signal generated by combining in an anti-phase manner the first output signal input through the input terminal 432 and the second output signal input through the input terminal 433. The first power amplifier circuit includes a carrier amplifier (power amplifier 21) that has the fifth input end and the fifth output end, the fifth input end being connected to the output terminal 102, the fifth output end being connected to the input terminal 432, and the harmonic wave phase shift circuit 22 that is connected to a path connecting the fifth output end to the input terminal 432 and is configured to shift a phase of a second-order harmonic wave in the first band. The second power amplifier circuit includes a peak amplifier (power amplifier 31) that has the sixth input end and the sixth output end, the sixth input end being connected to the output terminal 103, the sixth output end being connected to the second input end, and the harmonic wave phase shift circuit 32 that is connected to a path connecting the sixth output end to the second input end and is configured to shift the phase of the second-order harmonic wave. A phase shift difference obtained by subtracting the phase of the second-order harmonic wave at the fourth input end from the phase of the second-order harmonic wave at the third input end is smaller than 90 degrees.

Accordingly, compared to a conventional Doherty amplifier in which a harmonic wave phase shift circuit is not additionally provided, the second-order harmonic waves in the first band can be suppressed with high accuracy, and the quality of transmission signals and power efficiency can be improved.

Furthermore, for example, the amplifier circuit 1C further includes the splitter 10 that includes the input terminal 101 and the output terminals 102 and 103 and is configured to split a fundamental wave signal in a transmission band of the first band input to the input terminal 101, output from the output terminal 102 a first signal, and output from the output terminal 103 a second signal whose phase is −90 degrees with respect to a phase of the first signal. The anti-phase combiner circuit 40C includes the transformer 42 that has the input terminals 422 and 423 and the output terminal 421 and is configured to output from the output terminal 421 a third output signal generated by combining in an anti-phase manner a first output signal input through the input terminal 422 and a second output signal input through the input terminal 423, the phase shift circuit 23C that is connected between the power amplifier circuit 20 and the transformer 42 and is configured to shift phases of the fundamental wave and a second-order harmonic wave in the first band, and the phase shift circuit 33C that is connected between the power amplifier circuit 30 and the transformer 42 and is configured to shift the phases of the fundamental wave and the second-order harmonic wave in the first band in such a manner that the pass phase of the fundamental wave is −90 degrees with respect to the phase shift circuit 23C. The power amplifier circuit 20 includes the power amplifier 21 that has the fourth input end and the fourth output end, the fourth input end being connected to the output terminal 102, and the harmonic wave phase shift circuit 22 that is connected to a path connecting the fourth output end to the transformer 42 and is configured to shift the phase of the second-order harmonic wave. The power amplifier circuit 30 includes the power amplifier 31 that has the fifth input end and the fifth output end, the fifth input end being connected to the output terminal 103, and the harmonic wave phase shift circuit 32 that is connected to a path connecting the fifth output end to the transformer 42 and is configured to shift the phase of the second-order harmonic wave. A phase shift difference obtained by subtracting the phase of the second-order harmonic wave at the input terminal 423 from the phase of the second-order harmonic wave at the input terminal 422 is smaller than 90 degrees.

Accordingly, compared to a conventional balanced amplifier of an anti-phase combining type in which a harmonic wave phase shift circuit is not additionally provided, the second-order harmonic waves in the first band can be suppressed over a wide range. Therefore, the quality of transmission signals and power efficiency can be improved.

Furthermore, for example, in the amplifier circuit 1C, a first phase shift difference obtained by subtracting the pass phase of the second-order harmonic wave of the harmonic wave phase shift circuit 32 from the pass phase of the second-order harmonic wave of the harmonic wave phase shift circuit 22 is equal to a second phase shift difference obtained by subtracting the pass phase of the second-order harmonic wave of the phase shift circuit 33C from the pass phase of the second-order harmonic wave of the phase shift circuit 23C.

Accordingly, the second-order harmonic waves in the first band have an in-phase relationship between the input terminals 422 and 423 of the transformer 42 and are canceled. Thus, the amplifier circuit 1C in which the quality of transmission signals and power efficiency are improved can be provided.

Furthermore, for example, in the amplifier circuit 1C, the phase shift circuit 23C is configured in such a manner that the pass phases of the fundamental wave and the harmonic wave are +45 degrees, the phase shift circuit 33C is configured in such a manner that the pass phases of the fundamental wave and the harmonic wave are −45 degrees, the harmonic wave phase shift circuit 22 is configured in such a manner that the pass phase of the harmonic wave is +45 degrees, and the harmonic wave phase shift circuit 32 is configured in such a manner that the pass phase of the harmonic wave is −45 degrees.

Accordingly, the second-order harmonic waves in the first band have an in-phase relationship between the input terminals 422 and 423 of the transformer 42 and are canceled. Thus, the amplifier circuit 1C in which the quality of transmission signals and power efficiency are improved can be provided.

Furthermore, for example, the amplifier circuit 1F according to the sixth modification further includes the splitter 10 that includes the input terminal 101 and the output terminals 102 and 103 and is configured to split a fundamental wave signal in a transmission band of the first band input to the input terminal 101, output from the output terminal 102 a first signal, and output from the output terminal 103 a second signal whose phase is −90 degrees with respect to a phase of the first signal. The combiner circuit includes the 90-degree combiner 44 that includes the input terminal 442 (second input end), the input terminal 443 (third input end), and the output terminal 441 (third output end) and is configured to output from the output terminal 441 a third output signal generated by combining a first output signal input through the input terminal 442 and a signal obtained by shifting a phase of a second output signal input through the input terminal 443 to be +90 degrees with respect to a phase of the first output signal. The power amplifier circuit 20 includes the power amplifier 21 that has the fourth input end and the fourth output end, the fourth input end being connected to the output terminal 102, and the harmonic wave phase shift circuit 22 that is connected to a path connecting the fourth output end to the input terminal 442 and is configured to shift a phase of a second-order harmonic wave in the first band. The power amplifier circuit 30 includes the power amplifier 31 that has the fifth input end and the fifth output end, the fifth input end being connected to the output terminal 103, and the harmonic wave phase shift circuit 32 that is connected to a path connecting the fifth output end to the input terminal 443 and is configured to shift the phase of the second-order harmonic wave. A phase shift difference obtained by subtracting the phase of the second-order harmonic wave at the input terminal 443 from the phase of the second-order harmonic wave at the input terminal 442 is 90 degrees.

Accordingly, compared to a conventional balanced amplifier of a 90-degree combining type in which a harmonic wave phase shift circuit is not additionally provided, the second-order harmonic waves in the first band can be suppressed over a wide range. Therefore, the quality of transmission signals and power efficiency can be improved.

Furthermore, for example, in the amplifier circuit 1F, the harmonic wave phase shift circuit 22 is configured in such a manner that the pass phase of the harmonic wave is +45 degrees, and the harmonic wave phase shift circuit 32 is configured in such a manner that the pass phase of the harmonic wave is −45 degrees.

Accordingly, the second-order harmonic waves in the first band have a phase difference of 270 degrees between the input terminals 442 and 443 of the 90-degree combiner 44, become anti-phase at the 90-degree combiner 44, and are canceled. Thus, the amplifier circuit 1F in which the quality of transmission signals and power efficiency are improved can be provided.

Furthermore, the amplifier circuit 1 according to this embodiment (the amplifier circuit 1A according to the first modification and the amplifier circuit 1C according to the second modification) includes the splitter 10 that includes the input terminal 101 and the output terminals 102 and 103 and is configured to split a fundamental wave signal in a transmission band of the first band input to the input terminal 101, output from the output terminal 102 a first signal, and output from the output terminal 103 a second signal whose phase is −90 degrees with respect to a phase of the first signal, the power amplifier 21 that has the fourth input end and the fourth output end, the fourth input end being connected to the output terminal 102, the power amplifier 31 that has the fifth input end and the fifth output end, the fifth input end being connected to the output terminal 103, the in-phase combiner 41 that has the input terminals 402 and 403 and the output terminal 401 and is configured to output from the output terminal 401 a third output signal obtained by combining in an in-phase manner a first output signal output from the power amplifier 21 and input through the input terminal 402 and a second output signal output from the power amplifier 31 and input through the input terminal 403, the phase shift circuit 23 that is connected between the power amplifier 21 and the in-phase combiner 41 and is configured to shift phases of a fundamental wave and a second-order harmonic wave in the first band, the phase shift circuit 33 that is connected between the power amplifier 31 and the in-phase combiner 41 and is configured to shift the phases of the fundamental wave and the second-order harmonic wave in the first band in such a manner that the pass phase of the fundamental wave is +90 degrees with respect to the phase shift circuit 23, the harmonic wave phase shift circuit 22 (22A) that is connected to a path connecting the fourth output end and the input terminal 402 and is configured to shift the phase of the second-order harmonic wave, and the harmonic wave phase shift circuit 32 (32A) that is connected to a path connecting the fifth output end to the input terminal 403 and is configured to shift the phase of the second-order harmonic wave. A phase shift difference obtained by subtracting the phase of the second-order harmonic wave at the input terminal 403 from the phase of the second-order harmonic wave at the input terminal 402 is larger than 90 degrees.

Accordingly, compared to a conventional balanced amplifier of an in-phase combining type in which a harmonic wave phase shift circuit is not additionally provided, the second-order harmonic waves in the first band can be suppressed with high accuracy. Thus, the amplifier circuit can function as a balanced amplifier that is resistant to changes in the load, and the quality of transmission signals and power efficiency can be improved.

Furthermore, for example, in the amplifier circuit 1B, a first phase shift difference obtained by subtracting the pass phase of the second-order harmonic wave of the harmonic wave phase shift circuit 32 from the pass phase of the second-order harmonic wave of the harmonic wave phase shift circuit 22 is equal to a second phase shift difference obtained by subtracting the pass phase of the second-order harmonic wave of the phase shift circuit 23 from the pass phase of the second-order harmonic wave of the phase shift circuit 33.

Accordingly, the second-order harmonic waves in the first band have a phase difference of 180 degrees (anti-phase relationship) between the input terminals 402 and 403 of the in-phase combiner 41 and are canceled. Thus, the amplifier circuit 1B in which the quality of transmission signals and power efficiency are improved can be provided.

Furthermore, for example, in the amplifier circuit 1B, the phase shift circuit 23 is configured in such a manner that the pass phases of the fundamental wave and the second-order harmonic wave are −45 degrees, the phase shift circuit 33 is configured in such a manner that the pass phases of the fundamental wave and the second-order harmonic wave are +45 degrees, the harmonic wave phase shift circuit 22 is configured in such a manner that the pass phase of the harmonic wave is +45 degrees, and the harmonic wave phase shift circuit 32 is configured in such a manner that the pass phase of the harmonic wave is −45 degrees.

Accordingly, the second-order harmonic waves in the first band have a phase difference of 180 degrees (anti-phase relationship) between the input terminals 402 and 403 of the in-phase combiner 41 and are canceled. Thus, the amplifier circuit 1B in which the quality of transmission signals and power efficiency are improved can be provided.

Furthermore, for example, in the amplifier circuit 1B, the phase shift circuit 23 is configured in such a manner that the pass phase of the fundamental wave is −45 degrees and the pass phase of the harmonic wave is −X degrees (X>0), the phase shift circuit 33 is configured in such a manner that the pass phase of the fundamental wave is +45 degrees and the pass phase of the harmonic wave is +Y degrees (Y>0), the harmonic wave phase shift circuit 22 is configured in such a manner that the pass phase of the harmonic wave is +X degrees (X>0), and the harmonic wave phase shift circuit 32 is configured in such a manner that the pass phase of the harmonic wave is −Y degrees (Y>0).

Accordingly, the second-order harmonic waves in the first band have a phase difference of 180 degrees (anti-phase relationship) between the input terminals 402 and 403 of the in-phase combiner 41 and are canceled. Thus, the amplifier circuit 1B in which the quality of transmission signals and power efficiency are improved can be provided.

Furthermore, for example, in the amplifier circuit 1 (1A and 1B), the phase shift circuit 23 includes the inductor 231 that is connected between the fourth output end and the input terminal 402 and the capacitor 232 that is connected between a path connecting the inductor 231 to the input terminal 402 and the ground, and the phase shift circuit 33 includes the capacitor 331 that is connected between the fifth output end and the input terminal 403 and the inductor 332 that is connected between a path connecting the capacitor 331 to the input terminal 403 and the ground.

Accordingly, the phase shift circuit 23 can configure a low pass filter in which a fundamental wave band and a second-order harmonic wave band of the first band serve as a pass band, the pass phase of the fundamental wave in the first band can be −45 degrees, and the pass phase of the second-order harmonic wave can be −45 degrees (−X degrees: X>0). Furthermore, the phase shift circuit 33 can configure a high pass filter in which the fundamental wave band and the second-order harmonic wave band of the first band serve as a pass band, the pass phase of the fundamental wave in the first band can be +45 degrees, and the pass phase of the second-order harmonic wave can be +45 degrees (+Y degrees: Y>0).

Furthermore, for example, in the amplifier circuit 1 (1A and 1B), the harmonic wave phase shift circuit 22 (22A) includes an LC circuit including the inductor 221 and the capacitor 222 that are connected in series. The LC circuit is connected between a path connecting the fourth output end to the inductor 231 and the ground. The harmonic wave phase shift circuit 32 (32A) includes the capacitor 321 that is connected between a path connecting the fifth output end to the capacitor 331 and the ground.

Accordingly, the harmonic wave phase shift circuit 22 (22A) can configure a notch filter in which the fundamental wave band of the first band serves as a pass band and the second-order harmonic wave band serves as an attenuation band, the pass phase of the fundamental wave can be 0 degrees, and the pass phase of the second-order harmonic wave can be +45 degrees (+X degrees: X>0). Furthermore, the harmonic wave phase shift circuit 32 (32A) can configure a low pass filter in which the fundamental wave band of the first band serves as a pass band and the second-order harmonic wave serves as an attenuation band, the pass phase of the fundamental wave can be 0 degrees, and the pass phase of the second-order harmonic wave can be −45 degrees (−Y degrees: Y>0).

Furthermore, for example, in the amplifier circuit 1 (1A and 1B), the phase shift circuits 23 and 33 and the harmonic wave phase shift circuits 22 (22A) and 32 (32A) are included in a single semiconductor IC.

Accordingly, since the size of the amplifier circuit 1 (1A and 1B) can be reduced and the length of a signal wire from the power amplifiers 21 and 31 to the in-phase combiner 41 can be reduced, signal transfer loss in the amplifier circuit 1 (1A and 1B) can be reduced.

### Other Embodiments

Amplifier circuits according to embodiments of the present disclosure have been described above as an embodiment and modifications. However, amplifier circuits according to the present disclosure are not limited to the embodiments and modifications described above. Other embodiments implemented by combining component elements in the embodiments and modifications described above, modifications obtained by making various modifications conceivable by those skilled in the art to the embodiments and modifications described above without departing from the spirit of the present disclosure, and various types of equipment including an amplifier circuit described above are also included in the present disclosure.

For example, in the amplifier circuits according to the embodiments and modifications described above, second-order harmonic waves are used as harmonic waves. However, harmonic waves at third or higher order may be used.

For example, in the amplifier circuits according to the embodiments and the modifications described above, other circuit elements, wires, or the like may be inserted between paths connecting circuit elements and signal paths disclosed in the drawings.

Features of amplifier circuits described above based on embodiments described above will be described below.

<1> An amplifier circuit comprising:
a first power amplifier circuit that includes a first power amplifier;
a second power amplifier circuit that includes a second power amplifier in which a phase of a fundamental wave at an output end is delayed by 90 degrees with respect to the first power amplifier; and
a combiner circuit that is configured to combine a fundamental wave of a first output signal output from the first power amplifier circuit and a fundamental wave of a second output signal output from the second power amplifier circuit,
wherein the first power amplifier circuit is of an inverse class-E type, and
wherein the second power amplifier circuit is of a class-E type.

<2> The amplifier circuit according to <1>, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees with respect to a phase of the first signal,
wherein the combiner circuit includes
a combiner that has a second input end, a third input end, and a third output end and is configured to output from the third output end a third output signal generated by combining in an in-phase manner the first output signal input through the second input end and the second output signal input through the third input end,
a first phase shift circuit that is connected between the first power amplifier circuit and the combiner and is configured to shift phases of a fundamental wave and a harmonic wave in the first band, and
a second phase shift circuit that is connected between the second power amplifier circuit and the combiner and is configured to shift the phases of the fundamental wave and the harmonic wave in the first band in such a manner that a pass phase of the fundamental wave is +90 degrees with respect to the first phase shift circuit,
wherein the first power amplifier circuit includes
a first power amplifier that has a fourth input end and a fourth output end, the fourth input end being connected to the first output end, and
a first harmonic wave phase shift circuit that is connected to a path connecting the fourth output end to the second input end and is configured to shift the phase of the harmonic wave,
wherein the second power amplifier circuit includes
a second power amplifier that has a fifth input end and a fifth output end, the fifth input end being connected to the second output end, and
a second harmonic wave phase shift circuit that is connected to a path connecting the fifth output end to the third input end and is configured to shift the phase of the harmonic wave, and
wherein a phase shift difference obtained by subtracting the phase of the harmonic wave at the third input end from the phase of the harmonic wave at the second input end is larger than 90 degrees.

<3> The amplifier circuit according to <2>, wherein a first phase shift difference obtained by subtracting a pass phase of the harmonic wave of the second harmonic wave phase shift circuit from a pass phase of the harmonic wave of the first harmonic wave phase shift circuit is equal to a second phase shift difference obtained by subtracting a pass phase of the harmonic wave of the first phase shift circuit from a pass phase of the harmonic wave of the second phase shift circuit.

<4> The amplifier circuit according to <3>,
wherein the first phase shift circuit is configured in such a manner that the pass phases of the fundamental wave and the harmonic wave are −45 degrees,
wherein the second phase shift circuit is configured in such a manner that the pass phases of the fundamental wave and the harmonic wave are +45 degrees,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

<5> The amplifier circuit according to <3>,
wherein the first phase shift circuit is configured in such a manner that the pass phase of the fundamental wave is −45 degrees and the pass phase of the harmonic wave is −X degrees (X>0),
wherein the second phase shift circuit is configured in such a manner that the pass phase of the fundamental wave is +45 degrees and the pass phase of the harmonic wave is +Y degrees (Y>0),
wherein the first harmonic wave phase shift circuit is configured in such a manner that the pass phase of the harmonic wave is +X degrees (X>0), and
wherein the second harmonic wave phase shift circuit is configured in such a manner that the pass phase of the harmonic wave is −Y degrees (Y>0).

<6> The amplifier circuit according to <1>, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a phase shift line that has a second input end and a third output end and is configured to delay the fundamental wave of the first output signal input through the second input end by 90 degrees,
wherein the first power amplifier circuit includes
a carrier amplifier that has a third input end and a fourth output end, the third input end being connected to the first output end, the fourth output end being connected to the second input end, and
a first harmonic wave phase shift circuit that is connected to a path connecting the fourth output end to the second input end and is configured to shift a phase of a harmonic wave in the first band,
wherein the second power amplifier circuit includes
a peak amplifier that has a fourth input end and a fifth output end, the fourth input end being connected to the second output end, the fifth output end being connected to the third output end, and
a second harmonic wave phase shift circuit that is connected to a path connecting the fifth output end to the third output end and is configured to shift the phase of the harmonic wave, and
wherein a phase shift difference obtained by subtracting the phase of the harmonic wave from the fifth output end input to the third output end from the phase of the harmonic wave from the fourth output end input to the third output end is larger than 90 degrees.

<7> The amplifier circuit according to <1>, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a phase shift line that has a second input end and a third output end and is configured to delay the fundamental wave of the second output signal input through the second input end by 90 degrees, and
a transformer that has a third input end, a fourth input end, and a fourth output end and is configured to output from the fourth output end a third output signal generated by combining in an anti-phase manner the first output signal input through the third input end and the second output signal input through the fourth input end,
wherein the first power amplifier circuit includes
a carrier amplifier that has a fifth input end and a fifth output end, the fifth input end being connected to the first output end, the fifth output end being connected to the third input end, and
a first harmonic wave phase shift circuit that is connected to a path connecting the fifth output end to the third input end and is configured to shift a phase of a harmonic wave in the first band,
wherein the second power amplifier circuit includes
a peak amplifier that has a sixth input end and a sixth output end, the sixth input end being connected to the second output end, the sixth output end being connected to the second input end, and
a second harmonic wave phase shift circuit that is connected to a path connecting the sixth output end to the second input end and is configured to shift the phase of the harmonic wave, and
wherein a phase shift difference obtained by subtracting the phase of the harmonic wave at the fourth input end from the phase of the harmonic wave at the third input end is smaller than 90 degrees.

<8> The amplifier circuit according to <1>, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a transformer that has a second input end, a third input end, and a third output end and is configured to output from the third output end a third output signal generated by combining in an anti-phase manner the first output signal input through the second input end and the second output signal input through the third input end,
a first phase shift circuit that is connected between the first power amplifier circuit and the transformer and is configured to shift phases of a fundamental wave and a harmonic wave in the first band, and
a second phase shift circuit that is connected between the second power amplifier circuit and the transformer and is configured to shift the phases of the fundamental wave and the harmonic wave in the first band in such a manner that a pass phase of the fundamental wave is −90 degrees relative to the first phase shift circuit,
wherein the first power amplifier circuit includes
a first power amplifier that has a fourth input end and a fourth output end, the fourth input end being connected to the first output end, and
a first harmonic wave phase shift circuit that is connected to a path connecting the fourth output end to the second input end and is configured to shift the phase of the harmonic wave,
wherein the second power amplifier circuit includes
a second power amplifier that has a fifth input end and a fifth output end, the fifth input end being connected to the second output end, and
a second harmonic wave phase shift circuit that is connected to a path connecting the fifth output end to the third input end and is configured to shift the phase of the harmonic wave, and
wherein a phase shift difference obtained by subtracting the phase of the harmonic wave at the third input end from the phase of the harmonic wave at the second input end is smaller than 90 degrees.

<9> The amplifier circuit according to <8>, wherein a first phase shift difference obtained by subtracting a pass phase of the harmonic wave of the second harmonic wave phase shift circuit from a pass phase of the harmonic wave of the first harmonic wave phase shift circuit is equal to a second phase shift difference obtained by subtracting a pass phase of the harmonic wave of the second phase shift circuit from a pass phase of the harmonic wave of the first phase shift circuit.

<10> The amplifier circuit according to <9>,
wherein the first phase shift circuit is configured in such a manner that the pass phases of the fundamental wave and the harmonic wave are +45 degrees,
wherein the second phase shift circuit is configured in such a manner that the pass phases of the fundamental wave and the harmonic wave are −45 degrees,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

<11> The amplifier circuit according to <1>, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a combiner that has a second input end, a third input end, and a third output end and is configured to output from the third output end a third output signal generated by combining the first output signal input through the second input end and a signal obtained by shifting a phase of the second output signal input through the third input end to be +90 degrees with respect to a phase of the first output signal,
wherein the first power amplifier circuit includes a first power amplifier that has a fourth input end and a fourth output end, the fourth input end being connected to the first output end, and
a first harmonic wave phase shift circuit that is connected to a path connecting the fourth output end to the second input end and is configured to shift a phase of a harmonic wave in the first band,
wherein the second power amplifier circuit includes
a second power amplifier that has a fifth input end and a fifth output end, the fifth input end being connected to the second output end, and
a second harmonic wave phase shift circuit that is connected to a path connecting the fifth output end to the third input end and is configured to shift the phase of the harmonic wave, and
wherein a phase shift difference obtained by subtracting the phase of the harmonic wave at the second input end from the phase of the harmonic wave at the third input end is 90 degrees.

<12> The amplifier circuit according to <11>,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

<13> An amplifier circuit comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees with respect to a phase of the first signal;
a first power amplifier that has a fourth input end and a fourth output end, the fourth input end being connected to the first output end;
a second power amplifier that has a fifth input end and a fifth output end, the fifth input end being connected to the second output end;
a combiner that has a second input end, a third input end, and a third output end and is configured to output from the third output end a third output signal obtained by combining in an in-phase manner a first output signal output from the first power amplifier and input through the second input end and a second output signal output from the second power amplifier and input through the third input end;
a first phase shift circuit that is connected between the first power amplifier and the combiner and is configured to shift phases of a fundamental wave and a harmonic wave in the first band;
a second phase shift circuit that is connected between the second power amplifier and the combiner and is configured to shift the phases of the fundamental wave and the harmonic wave in the first band in such a manner that a pass phase of the fundamental wave is +90 degrees with respect to the first phase shift circuit;
a first harmonic wave phase shift circuit that is connected to a path connecting the fourth output end to the second input end and is configured to shift the phase of the harmonic wave; and
a second harmonic wave phase shift circuit that is connected to a path connecting the fifth output end to the third input end and is configured to shift the phase of the harmonic wave,
wherein a phase shift difference obtained by subtracting the phase of the harmonic wave at the third input end from the phase of the harmonic wave at the second input end is larger than 90 degrees.

<14> The amplifier circuit according to <13>, wherein a first phase shift difference obtained by subtracting a pass phase of the harmonic wave of the second harmonic wave phase shift circuit from a pass phase of the harmonic wave of the first harmonic wave phase shift circuit is equal to a second phase shift difference obtained by subtracting a pass phase of the harmonic wave of the first phase shift circuit from a pass phase of the harmonic wave of the second phase shift circuit.

<15> The amplifier circuit according to <14>,
wherein the first phase shift circuit is configured in such a manner that the pass phases of the fundamental wave and the harmonic wave are −45 degrees,
wherein the second phase shift circuit is configured in such a manner that the pass phases of the fundamental wave and the harmonic wave are +45 degrees,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

<16> The amplifier circuit according to <14>,
wherein the first phase shift circuit is configured in such a manner that the pass phase of the fundamental wave is −45 degrees and the pass phase of the harmonic wave is −X degrees (X>0),
wherein the second phase shift circuit is configured in such a manner that the pass phase of the fundamental wave is +45 degrees and the pass phase of the harmonic wave is +Y degrees (Y>0),
wherein the first harmonic wave phase shift circuit is configured in such a manner that the pass phase of the harmonic wave is +X degrees (X>0), and
wherein the second harmonic wave phase shift circuit is configured in such a manner that the pass phase of the harmonic wave is −Y degrees (Y>0).

<17> The amplifier circuit according to any one of <13> to <16>,
wherein the first phase shift circuit includes
a first inductor that is connected between the fourth output end and the second input end, and
a first capacitor that is connected between a path connecting the first inductor to the second input end and a ground, and
wherein the second phase shift circuit includes
a second capacitor that is connected between the fifth output end and the third input end, and
a second inductor that is connected between a path connecting the second capacitor to the third input end and the ground.

<18> The amplifier circuit according to <17>,
wherein the first harmonic wave phase shift circuit includes
an LC circuit that includes a third inductor and a third capacitor that are connected in series,
wherein the LC circuit is connected between a path connecting the fourth output end to the first inductor and the ground, and
wherein the second harmonic wave phase shift circuit includes
a fourth capacitor that is connected between a path connecting the fifth output end to the second capacitor and the ground.

<19> The amplifier circuit according to any one of <13> to <18>, wherein the first phase shift circuit, the second phase shift circuit, the first harmonic wave phase shift circuit, and the second harmonic wave phase shift circuit are included in a single semiconductor IC.

The present disclosure can be widely used as an amplifier circuit arranged in a front end part in a communication apparatus such as a mobile phone.

What is claimed is:

1. An amplifier circuit comprising:
a first power amplifier circuit that includes a first power amplifier;
a second power amplifier circuit that includes a second power amplifier in which a phase of a fundamental wave at an output end is delayed by 90 degrees with respect to the first power amplifier; and
a combiner circuit that is configured to combine a fundamental wave of a first output signal output from the first power amplifier circuit and a fundamental wave of a second output signal output from the second power amplifier circuit,
wherein the first power amplifier circuit is of an inverse class-E type, and
wherein the second power amplifier circuit is of a class-E type.

2. The amplifier circuit according to claim 1, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees with respect to a phase of the first signal,
wherein the combiner circuit includes
a combiner that has a second input end, a third input end, and a third output end and is configured to output from the third output end a third output signal generated by combining in an in-phase manner the first output signal input through the second input end and the second output signal input through the third input end,
a first phase shift circuit that is connected between the first power amplifier circuit and the combiner and is configured to shift phases of a fundamental wave and a harmonic wave in the first band, and
a second phase shift circuit that is connected between the second power amplifier circuit and the combiner and is configured to shift the phases of the fundamental wave and the harmonic wave in the first band in such a manner that a pass phase of the fundamental wave is +90 degrees with respect to the first phase shift circuit,
wherein the first power amplifier circuit includes
a first power amplifier that has a fourth input end and a fourth output end, the fourth input end being connected to the first output end, and
a first harmonic wave phase shift circuit that is connected to a path connecting the fourth output end to the second input end and is configured to shift the phase of the harmonic wave,
wherein the second power amplifier circuit includes
a second power amplifier that has a fifth input end and a fifth output end, the fifth input end being connected to the second output end, and
a second harmonic wave phase shift circuit that is connected to a path connecting the fifth output end to the third input end and is configured to shift the phase of the harmonic wave, and
wherein a phase shift difference obtained by subtracting the phase of the harmonic wave at the third input end from the phase of the harmonic wave at the second input end is larger than 90 degrees.

3. The amplifier circuit according to claim 2, wherein a first phase shift difference obtained by subtracting a pass phase of the harmonic wave of the second harmonic wave phase shift circuit from a pass phase of the harmonic wave of the first harmonic wave phase shift circuit is equal to a second phase shift difference obtained by subtracting a pass phase of the harmonic wave of the first phase shift circuit from a pass phase of the harmonic wave of the second phase shift circuit.

4. The amplifier circuit according to claim 3,
wherein the first phase shift circuit is configured in such a manner that the pass phases of the fundamental wave and the harmonic wave are −45 degrees,
wherein the second phase shift circuit is configured in such a manner that the pass phases of the fundamental wave and the harmonic wave are +45 degrees,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

5. The amplifier circuit according to claim 3,
wherein the first phase shift circuit is configured in such a manner that the pass phase of the fundamental wave is −45 degrees and the pass phase of the harmonic wave is −X degrees (X>0),
wherein the second phase shift circuit is configured in such a manner that the pass phase of the fundamental wave is +45 degrees and the pass phase of the harmonic wave is +Y degrees (Y>0),
wherein the first harmonic wave phase shift circuit is configured in such a manner that the pass phase of the harmonic wave is +X degrees (X>0), and
wherein the second harmonic wave phase shift circuit is configured in such a manner that the pass phase of the harmonic wave is −Y degrees (Y>0).

6. The amplifier circuit according to claim 1, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a phase shift line that has a second input end and a third output end and is configured to delay the fundamental wave of the first output signal input through the second input end by 90 degrees,
wherein the first power amplifier circuit includes
a carrier amplifier that has a third input end and a fourth output end, the third input end being connected to the first output end, the fourth output end being connected to the second input end, and
a first harmonic wave phase shift circuit that is connected to a path connecting the fourth output end to the second input end and is configured to shift a phase of a harmonic wave in the first band,
wherein the second power amplifier circuit includes
a peak amplifier that has a fourth input end and a fifth output end, the fourth input end being connected to the second output end, the fifth output end being connected to the third output end, and
a second harmonic wave phase shift circuit that is connected to a path connecting the fifth output end to the third output end and is configured to shift the phase of the harmonic wave, and
wherein a phase shift difference obtained by subtracting the phase of the harmonic wave from the fifth output end input to the third output end from the phase of the harmonic wave from the fourth output end input to the third output end is larger than 90 degrees.

7. The amplifier circuit according to claim 1, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a phase shift line that has a second input end and a third output end and is configured to delay the fundamental wave of the second output signal input through the second input end by 90 degrees, and
a transformer that has a third input end, a fourth input end, and a fourth output end and is configured to output from the fourth output end a third output signal generated by combining in an anti-phase manner the first output signal input through the third input end and the second output signal input through the fourth input end,
wherein the first power amplifier circuit includes
a carrier amplifier that has a fifth input end and a fifth output end, the fifth input end being connected to the first output end, the fifth output end being connected to the third input end, and
a first harmonic wave phase shift circuit that is connected to a path connecting the fifth output end to the third input end and is configured to shift a phase of a harmonic wave in the first band,
wherein the second power amplifier circuit includes
a peak amplifier that has a sixth input end and a sixth output end, the sixth input end being connected to the second output end, the sixth output end being connected to the second input end, and
a second harmonic wave phase shift circuit that is connected to a path connecting the sixth output end to the second input end and is configured to shift the phase of the harmonic wave, and
wherein a phase shift difference obtained by subtracting the phase of the harmonic wave at the fourth input end from the phase of the harmonic wave at the third input end is smaller than 90 degrees.

8. The amplifier circuit according to claim 1, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a transformer that has a second input end, a third input end, and a third output end and is configured to output from the third output end a third output signal generated by combining in an anti-phase manner the first output signal input through the second input end and the second output signal input through the third input end,
a first phase shift circuit that is connected between the first power amplifier circuit and the transformer and is configured to shift phases of a fundamental wave and a harmonic wave in the first band, and
a second phase shift circuit that is connected between the second power amplifier circuit and the transformer and is configured to shift the phases of the fundamental wave and the harmonic wave in the first band in such a manner that a pass phase of the fundamental wave is −90 degrees relative to the first phase shift circuit,
wherein the first power amplifier circuit includes
a first power amplifier that has a fourth input end and a fourth output end, the fourth input end being connected to the first output end, and
a first harmonic wave phase shift circuit that is connected to a path connecting the fourth output end to the second input end and is configured to shift the phase of the harmonic wave,
wherein the second power amplifier circuit includes
a second power amplifier that has a fifth input end and a fifth output end, the fifth input end being connected to the second output end, and
a second harmonic wave phase shift circuit that is connected to a path connecting the fifth output end to the third input end and is configured to shift the phase of the harmonic wave, and
wherein a phase shift difference obtained by subtracting the phase of the harmonic wave at the third input end from the phase of the harmonic wave at the second input end is smaller than 90 degrees.

9. The amplifier circuit according to claim 8, wherein a first phase shift difference obtained by subtracting a pass phase of the harmonic wave of the second harmonic wave phase shift circuit from a pass phase of the harmonic wave of the first harmonic wave phase shift circuit is equal to a second phase shift difference obtained by subtracting a pass phase of the harmonic wave of the second phase shift circuit from a pass phase of the harmonic wave of the first phase shift circuit.

10. The amplifier circuit according to claim 9,
wherein the first phase shift circuit is configured in such a manner that the pass phases of the fundamental wave and the harmonic wave are +45 degrees,
wherein the second phase shift circuit is configured in such a manner that the pass phases of the fundamental wave and the harmonic wave are −45 degrees,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

11. The amplifier circuit according to claim 1, further comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees relative to a phase of the first signal,
wherein the combiner circuit includes
a combiner that has a second input end, a third input end, and a third output end and is configured to output from the third output end a third output signal generated by combining the first output signal input through the second input end and a signal obtained by shifting a phase of the second output signal input through the third input end to be +90 degrees with respect to a phase of the first output signal,
wherein the first power amplifier circuit includes
a first power amplifier that has a fourth input end and a fourth output end, the fourth input end being connected to the first output end, and
a first harmonic wave phase shift circuit that is connected to a path connecting the fourth output end to the second input end and is configured to shift a phase of a harmonic wave in the first band,
wherein the second power amplifier circuit includes
a second power amplifier that has a fifth input end and a fifth output end, the fifth input end being connected to the second output end, and
a second harmonic wave phase shift circuit that is connected to a path connecting the fifth output end to the third input end and is configured to shift the phase of the harmonic wave, and
wherein a phase shift difference obtained by subtracting the phase of the harmonic wave at the second input end from the phase of the harmonic wave at the third input end is 90 degrees.

12. The amplifier circuit according to claim 11,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

13. An amplifier circuit comprising:
a splitter that has a first input end, a first output end, and a second output end and is configured to split a fundamental wave signal in a transmission band of a first band input to the first input end, output from the first output end a first signal, and output from the second output end a second signal whose phase is −90 degrees with respect to a phase of the first signal;
a first power amplifier that has a fourth input end and a fourth output end, the fourth input end being connected to the first output end;
a second power amplifier that has a fifth input end and a fifth output end, the fifth input end being connected to the second output end;
a combiner that has a second input end, a third input end, and a third output end and is configured to output from the third output end a third output signal obtained by combining in an in-phase manner a first output signal output from the first power amplifier and input through the second input end and a second output signal output from the second power amplifier and input through the third input end;
a first phase shift circuit that is connected between the first power amplifier and the combiner and is configured to shift phases of a fundamental wave and a harmonic wave in the first band;
a second phase shift circuit that is connected between the second power amplifier and the combiner and is configured to shift the phases of the fundamental wave and the harmonic wave in the first band in such a manner that a pass phase of the fundamental wave is +90 degrees with respect to the first phase shift circuit;
a first harmonic wave phase shift circuit that is connected to a path connecting the fourth output end to the second input end and is configured to shift the phase of the harmonic wave; and
a second harmonic wave phase shift circuit that is connected to a path connecting the fifth output end to the third input end and is configured to shift the phase of the harmonic wave,
wherein a phase shift difference obtained by subtracting the phase of the harmonic wave at the third input end from the phase of the harmonic wave at the second input end is larger than 90 degrees.

14. The amplifier circuit according to claim 13, wherein a first phase shift difference obtained by subtracting a pass phase of the harmonic wave of the second harmonic wave phase shift circuit from a pass phase of the harmonic wave of the first harmonic wave phase shift circuit is equal to a second phase shift difference obtained by subtracting a pass phase of the harmonic wave of the first phase shift circuit from a pass phase of the harmonic wave of the second phase shift circuit.

15. The amplifier circuit according to claim 14,
wherein the first phase shift circuit is configured in such a manner that the pass phases of the fundamental wave and the harmonic wave are −45 degrees,
wherein the second phase shift circuit is configured in such a manner that the pass phases of the fundamental wave and the harmonic wave are +45 degrees,
wherein the first harmonic wave phase shift circuit is configured in such a manner that the pass phase of the harmonic wave is +45 degrees, and
wherein the second harmonic wave phase shift circuit is configured in such a manner that the pass phase of the harmonic wave is −45 degrees.

16. The amplifier circuit according to claim 14,
wherein the first phase shift circuit is configured in such a manner that the pass phase of the fundamental wave is −45 degrees and the pass phase of the harmonic wave is −X degrees (X>0),
wherein the second phase shift circuit is configured in such a manner that the pass phase of the fundamental wave is +45 degrees and the pass phase of the harmonic wave is +Y degrees (Y>0),
wherein the first harmonic wave phase shift circuit is configured in such a manner that the pass phase of the harmonic wave is +X degrees (X>0), and
wherein the second harmonic wave phase shift circuit is configured in such a manner that the pass phase of the harmonic wave is −Y degrees (Y>0).

17. The amplifier circuit according to claim 16,
wherein the first phase shift circuit includes
a first inductor that is connected between the fourth output end and the second input end, and
a first capacitor that is connected between a path connecting the first inductor to the second input end and a ground, and
wherein the second phase shift circuit includes a second capacitor that is connected between the fifth output end and the third input end, and
a second inductor that is connected between a path connecting the second capacitor to the third input end and the ground.

18. The amplifier circuit according to claim 17,
wherein the first harmonic wave phase shift circuit includes
an LC circuit that includes a third inductor and a third capacitor that are connected in series,
wherein the LC circuit is connected between a path connecting the fourth output end to the first inductor and the ground, and
wherein the second harmonic wave phase shift circuit includes
a fourth capacitor that is connected between a path connecting the fifth output end to the second capacitor and the ground.

19. The amplifier circuit according to claim 16, wherein the first phase shift circuit, the second phase shift circuit, the first harmonic wave phase shift circuit, and the second harmonic wave phase shift circuit are included in a single semiconductor IC.

20. The amplifier circuit according to claim 13, wherein the first phase shift circuit, the second phase shift circuit, the first harmonic wave phase shift circuit, and the second harmonic wave phase shift circuit are included in a single semiconductor IC.
